(19) United States
(12) Patent Application Publication
(10) Pub. No.: US 2017/0186782 A1
(43) Pub. Date: Jun. 29, 2017

(54) PIXEL CIRCUIT OF ACTIVE-MATRIX LIGHT-EMITTING DIODE AND DISPLAY PANEL HAVING THE SAME

(71) Applicant: InnoLux Corporation, Miao-Li County (TW)

(72) Inventors: Kuanfeng LEE, Miao-Li County (TW); Kung-Chen KUO, Miao-Li County (TW); Lien-Hsiang CHEN, Miao-Li County (TW); Yu-Sheng TSAI, Miao-Li County (TW)

(21) Appl. No.: 15/384,590

(22) Filed: Dec. 20, 2016

Related U.S. Application Data
(60) Provisional application No. 62/387,213, filed on Dec. 24, 2015.
(60) Provisional application No. 62/382,281, filed on Sep. 1, 2016.
(60) Provisional application No. 62/429,162, filed on Dec. 2, 2016.

(30) Foreign Application Priority Data
Jun. 17, 2016 (TW) 105119032

(51) Int. Cl. H01L 27/12; H01L 29/417

(52) U.S. Cl. CPC H01L 27/1251; H01L 27/1225; H01L 29/41733; H01L 27/1248; H01L 27/124; H01L 29/7869

(57) ABSTRACT

A display includes a pixel circuit. The pixel circuit includes a light emitting diode, a first transistor, a second transistor and a third transistor. The first transistor includes a first semiconductor layer. The first transistor has a first control terminal, a second terminal, and a third terminal electrically connected to the light emitting diode. The second transistor includes a second semiconductor layer, and is electrically connected to the third terminal. The third transistor is electrically connected to the first control terminal. A material of the first semiconductor layer is different from a material of the second semiconductor layer.

### BACKGROUND

1. Field of the Disclosure

The present disclosure relates to the technical field of liquid crystal display panels and, more particularly, to a pixel circuit of active-matrix light-emitting diode and a display panel having the same.

2. Description of Related Art

Typically, based on the substrate manufacturing process, the type of driving transistor for active-matrix light-emitting diode pixel can be divided into P-type and N-type. FIG. 1 is a 2T1C pixel circuit with an N-type driving transistor, which is used to drive an inverted light-emitting diode.

The N-type driving transistor (NTFT_dri) has a gate/source voltage (Vgs) that corresponds to a data level and a low level (ELVSS). For the known N-type driving transistor (NTFT_dri), it may suffer a problem of threshold voltage variation. That is, due to the polycrystalline process, the threshold voltages Vt of different N-type driving transistors are varied owing to different locations of the N-type driving transistors. Accordingly, when driving voltages with the same value are respectively inputted to two N-type driving transistors with the same size, the resultant output currents are not of the same value, which may cause a problem of mura or poor brightness uniformity. Therefore, it is desirable to provide an improved pixel circuit to mitigate and/or obviate the aforementioned problems.

### SUMMARY

According to one aspect of the present disclosure, there is provided a display which comprises a pixel circuit. The pixel circuit comprises a light emitting diode, a first transistor, a second transistor and a third transistor. The first transistor comprises a first semiconductor layer. The first transistor has a first control terminal, a second terminal and a third terminal, and the third terminal is electrically connected to the light emitting diode. The second transistor comprises a second semiconductor layer, and the second transistor is electrically connected to the third terminal. The third transistor is electrically connected to the first control terminal. A material of the first semiconductor layer is different from a material of the second semiconductor layer.

According to another aspect of the present disclosure, there is provided a display which comprises pixel circuit. The pixel circuit comprises a light emitting diode, a first transistor, a second transistor and a third transistor. The first transistor has a first control terminal, a second terminal and a third terminal, and the third terminal is electrically connected to the light emitting diode. The second transistor comprises a second semiconductor layer and the second transistor is electrically connected to the third terminal. The third transistor comprises a third semiconductor layer and the third transistor is electrically connected to the first control terminal. A material of the second semiconductor layer is different from a material of the third semiconductor layer.

The object of the present disclosure is to provide a pixel circuit of active-matrix light-emitting diode and a display panel having the same, in which the light-emitting transistor of the pixel circuit is a polysilicon transistor that has a large current in its turn-on state thereby providing a large driving capability to drive the light-emitting diode. Furthermore, the driving transistor of the pixel circuit is an oxide semiconductor transistor that has a relatively low leakage current, with which the threshold voltage variation of the driving transistor can be eliminated, so as to enable the driving transistor to provide a stable driving current to the light emitting diode for mitigating the mura or poor brightness uniformity.

Another object of the present disclosure is to provide a pixel circuit of active-matrix light-emitting diode with a commonly-shared gate stack-up structure which can dramatically reduce the layout area.

Other objects, advantages, and novel features of the present disclosure will become more apparent from the following detailed description when taken in conjunction with the accompanying drawings.

### BRIEF DESCRIPTION OF THE DRAWINGS

FIG. 1 is a 2T1C pixel circuit with an N-type driving transistor;

FIG. 2 schematically illustrates a display panel with pixel circuits of active-matrix light-emitting diode according to the present disclosure;

FIG. 3 is a circuit diagram of a pixel circuit of active-matrix light-emitting diode according to a first embodiment of the present disclosure;

FIG. 4a to FIG. 4d are schematic diagrams illustrating the operation of the pixel circuit of FIG. 3 according to the present disclosure;

FIG. 5 schematically illustrates currents of the polysilicon transistor, the oxide semiconductor transistor, and the amorphous silicon (a-Si) transistor;

FIG. 6 schematically illustrates a simulation result for the pixel circuit of FIG. 3 according to the present disclosure;

FIG. 7 schematically illustrates another simulation result for the pixel circuit of FIG. 3 according to the present disclosure;

FIG. 8 schematically illustrates still another simulation result for the pixel circuit of FIG. 3 according to the present disclosure;

FIG. 9 is a schematic view illustrating an application of the pixel circuit of FIG. 3 according to the present disclosure;

FIG. 10 is a schematic view illustrating another application of the pixel circuit of FIG. 3 according to the present disclosure;

FIG. 11 is a schematic view illustrating still another application of the pixel circuit of FIG. 3 according to the present disclosure;

FIG. 12 is a circuit diagram of a pixel circuit of active-matrix light-emitting diode according to a second embodiment of the present disclosure;

FIG. 13 is schematic view illustrating an application of the pixel circuit of FIG. 12 according to the present disclosure;

FIG. 14 is schematic view illustrating another application of the pixel circuit of FIG. 12 according to the present disclosure;

FIG. 15 is schematic view illustrating still another application of the pixel circuit of FIG. 12 according to the present disclosure;

FIG. 16 is a circuit diagram of a pixel circuit of active-matrix light-emitting diode according to a third embodiment of the present disclosure;

FIG. 17 is schematic view illustrating an application of the pixel circuit of FIG. 16 according to the present disclosure;

FIG. 18 is schematic view illustrating another application of the pixel circuit of FIG. 16 according to the present disclosure;

FIG. 19 is schematic view illustrating still another application of the pixel circuit of FIG. 16 according to the present disclosure;

FIG. 20a to FIG. 20d are schematic diagrams illustrating the operation of the pixel circuit of FIG. 15 according to the present disclosure;

FIG. 21 is schematic view illustrating current compensation for the light-emitting diode of the pixel circuit according to the present disclosure;

FIG. 22 is a circuit diagram of a pixel circuit of active-matrix light-emitting diode according to a fourth embodiment of the present disclosure;

FIG. 23 is schematic view illustrating an application of the pixel circuit of FIG. 22 according to the present disclosure;

FIG. 24 is schematic view illustrating another application of the pixel circuit of FIG. 22 according to the present disclosure;

FIG. 25 is schematic view illustrating still another application of the pixel circuit of FIG. 22 according to the present disclosure;

FIG. 26 is a circuit diagram of a pixel circuit of active-matrix light-emitting diode according to a fifth embodiment of the present disclosure;

FIG. 27 is schematic view illustrating an application of the pixel circuit of FIG. 26 according to the present disclosure;

FIG. 28 is schematic view illustrating another application of the pixel circuit of FIG. 26 according to the present disclosure;

FIG. 29 is schematic view illustrating still another application of the pixel circuit of FIG. 26 according to the present disclosure;

FIG. 30 is a circuit diagram of a pixel circuit of active-matrix light-emitting diode according to a sixth embodiment of the present disclosure;

FIG. 31 is schematic diagram illustrating the operation of the pixel circuit of FIG. 30 according to the present disclosure;

FIG. 32 is a circuit diagram of a pixel circuit of active-matrix light-emitting diode according to a seventh embodiment of the present disclosure;

FIG. 33 is a circuit diagram of a pixel circuit of active-matrix light-emitting diode according to an eighth embodiment of the present disclosure;

FIG. 34 is a circuit diagram of a pixel circuit of active-matrix light-emitting diode according to a ninth embodiment of the present disclosure;

FIG. 35 is schematic diagram illustrating the operation of the pixel circuit of FIG. 34 according to the present disclosure;

FIG. 36 is a circuit diagram of a pixel circuit of active-matrix light-emitting diode according to a tenth embodiment of the present disclosure;

FIG. 37a to FIG. 37c are schematic diagrams illustrating the operation of the pixel circuit of FIG. 36 according to the present disclosure;

FIG. 38 is a circuit diagram of a pixel circuit of active-matrix light-emitting diode according to an eleventh embodiment of the present disclosure;

FIG. 39a to FIG. 39c are schematic diagrams illustrating the operation of the pixel circuit of FIG. 38 according to the present disclosure;

FIG. 40 is a schematic diagram illustrating the transistors type combination of the pixel circuit in FIG. 3 according to the present disclosure;

FIG. 41 is a schematic diagram illustrating the gate stack-up structure of the first transistor and the second transistor in FIG. 3 according to the present disclosure;

FIG. 42 is another schematic diagram illustrating the transistors type combination of the pixel circuit in FIG. 3 according to the present disclosure;

FIG. 43 is another schematic diagram illustrating the gate stack-up structure of the first transistor and the second transistor in FIG. 3 according to the present disclosure;

FIG. 44 is still another schematic diagram illustrating the transistors type combination of the pixel circuit in FIG. 3 according to the present disclosure;

FIG. 45 is still another schematic diagram illustrating the gate stack-up structure of the second transistor and the third transistor in FIG. 3 according to the present disclosure;

FIG. 46 is still another schematic diagram illustrating the transistors type combination of the pixel circuit in FIG. 3 according to the present disclosure; and

FIG. 47 is still another schematic diagram illustrating the gate stack-up structure of the second transistor and the third transistor in FIG. 3 according to the present disclosure.

### DESCRIPTION OF THE EMBODIMENTS

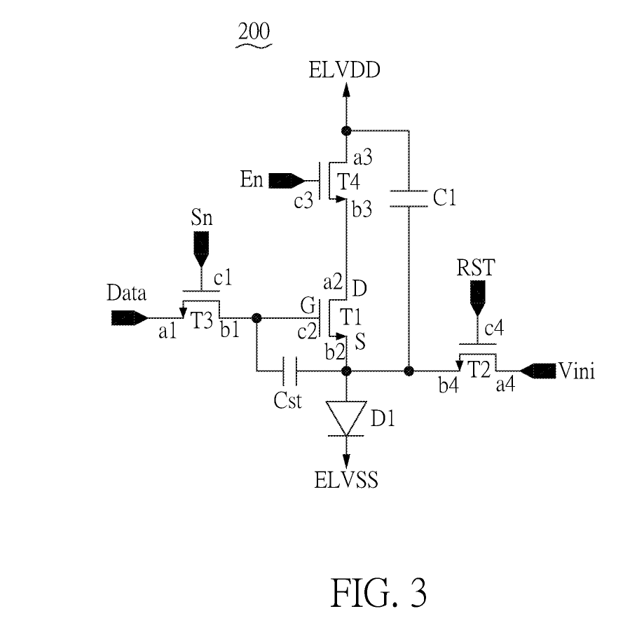

FIG. 40 is a schematic diagram illustrating the combination type of transistors of the pixel circuit 200 in FIG. 3 according to the present disclosure. As shown, for better performance for driving circuit, the first transistor (T1) and the second transistor (T2) comprise different semiconductor layers. That is, when the first transistor (T1) is a transistor comprising the silicon semiconductor layer, the pixel circuit 200 may have a better stability, where the silicon semiconductor layer can be a LTPS layer or amorphous silicon layer. When the second transistor (T2) is a transistor comprising an oxide semiconductor layer, the low leakage current can prevent inaccurate current flowing through the light-emitting diode (D1), where the light emitting diode can be an organic light emitting diode or a LED chip, and the oxide semiconductor layer can be an IGZO layer.

When the first transistor (T1) is a transistor comprising a silicon semiconductor layer and the second transistor (T2) is a transistor comprising an oxide semiconductor layer, the third transistor (T3) and the fourth transistor (T4) are each a transistor comprising the silicon semiconductor layer or a transistor comprising the oxide semiconductor layer. In the combination type 1, each of the third transistor (T3) and the fourth transistor (T4) comprises the silicon semiconductor layer. In the combination type 2, the third transistor (T3) comprises the oxide semiconductor layer and the fourth transistor (T4) comprises the silicon semiconductor layer. In the combination type 3, the third transistor (T3) comprises the silicon semiconductor layer and the fourth transistor (T4) comprises the oxide semiconductor layer. In the combination type 4, each of the third transistor (T3) and the fourth transistor (T4) comprises the oxide semiconductor layer.

In another embodiment, FIG. 41 is a schematic diagram illustrating the gate stack-up structure of the first transistor (T1) and the second transistor (T2) in FIG. 3. As shown in FIG. 41, the first transistor (T1) is a transistor comprising the silicon semiconductor layer and the second transistor (T2) is a transistor comprising the oxide semiconductor layer, where the silicon semiconductor layer can be a LTPS layer or amorphous silicon layer and the oxide semiconductor layer can be an IGZO layer. As shown, the first gate electrode (GE IGZO) of the second transistor (T2) is overlapped with the oxide semiconductor layer. In another embodiment, when the second transistor (T2) is a dual-gate structure, the second gate electrode (not shown) of the second transistor (T2) is also overlapped with the oxide semiconductor layer. The dual-gate structure is well-known to the person skilled in the art according to the illustration of FIG. 41 of the present disclosure, and therefore is not repeated again.

As in the combination type 2 and the combination type 4 of FIG. 40, the third transistor (T3) comprises an oxide semiconductor layer. As in the combination type 1 and the combination type 3 of FIG. 40, the third transistor (T3) comprises a silicon semiconductor layer.

As in the combination type 3 and the combination type 4 of FIG. 40, the fourth transistor (T4) comprises an oxide semiconductor layer. As in the combination type 1 and the combination type 2 of FIG. 40, the fourth transistor (T4) comprises a silicon semiconductor layer.

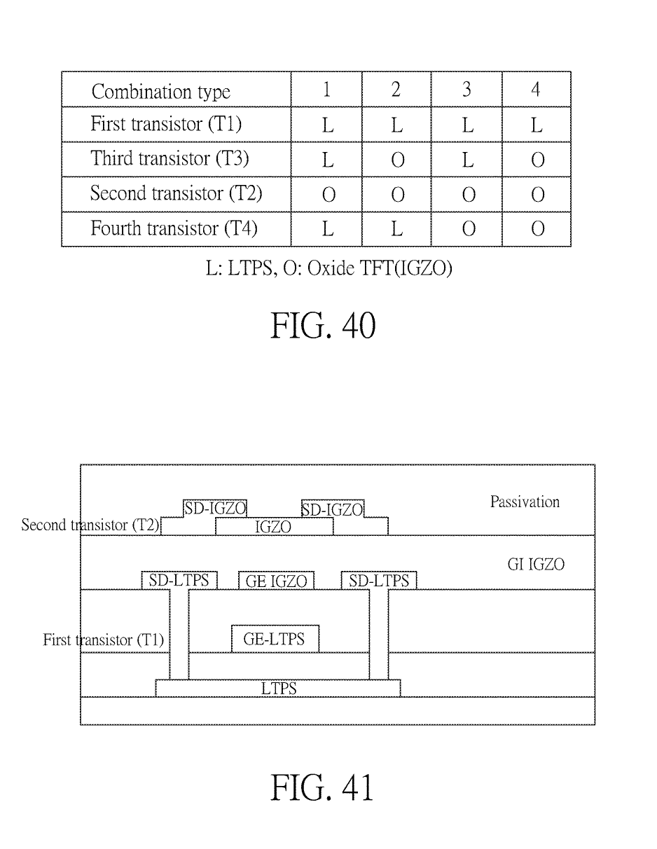

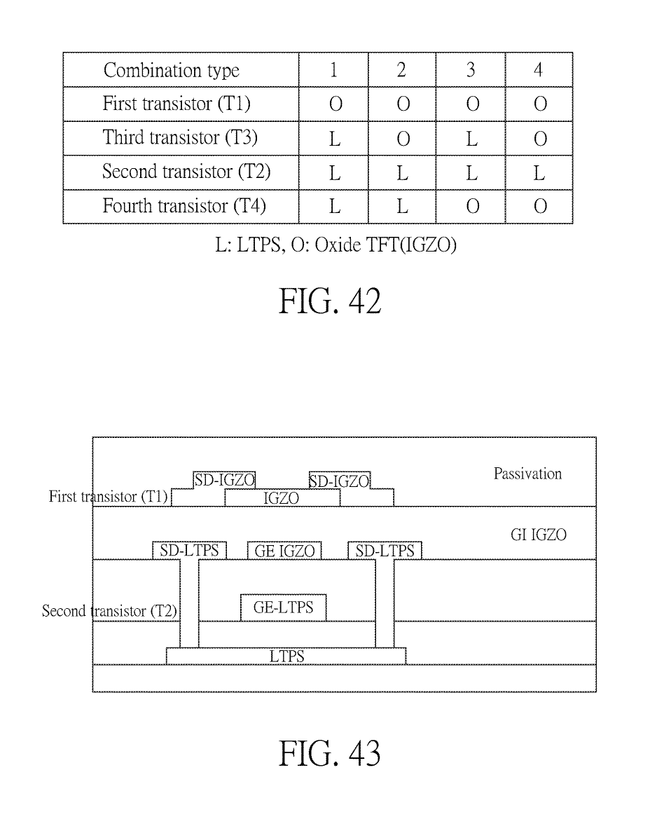

FIG. 42 is another schematic diagram illustrating the combination type of transistors of the pixel circuit 200 in FIG. 3 according to the present disclosure. As shown, for better performance for driving circuit, the first transistor (T1) and the second transistor (T2) comprise different semiconductor layers. That is, when the first transistor (T1) is a transistor comprising the oxide semiconductor layer, owing to low threshold voltage variation of the oxide semiconductor layer, the pixel circuit 200 has better threshold voltage uniformity, where the oxide semiconductor layer can be an IGZO layer. When the second transistor (T2) is a transistor comprising a silicon semiconductor layer, owing to the high mobility of the silicon semiconductor layer, the pixel circuit 200 has better reset speed, where the silicon semiconductor layer is a LTPS layer.

When the first transistor (T1) is a transistor comprising the oxide semiconductor layer and the second transistor (T2) is a transistor comprising the silicon semiconductor layer, the third transistor (T3) and the fourth transistor (T4) are each a transistor comprising the silicon semiconductor layer or a transistor comprising the oxide semiconductor layer. The combination types are similar to FIG. 40, and therefore are not repeated again.

In another embodiment, FIG. 43 is another schematic diagram illustrating the gate stack-up structure of the first transistor (T1) and the second transistor (T2) in FIG. 3. As shown in FIG. 43, the first transistor (T1) is a transistor comprising an oxide semiconductor layer, and the second transistor (T2) is a transistor comprising a silicon semiconductor layer, where the silicon semiconductor layer can be a LTPS layer or amorphous silicon layer and the oxide semiconductor layer can be an IGZO layer. As shown, the first gate electrode (GE LTPS) of the first transistor (T1) is overlapped with silicon semiconductor layer. In another embodiment, when the second transistor (T2) is a dual-gate structure, the second gate electrode (not shown) of the second transistor (T2) is also overlapped with the silicon semiconductor layer. The dual-gate structure is well-known to the person skilled in the art according to the illustration of FIG. 43 of the present disclosure, and therefore is not repeated again.

As in the combination type 2 and the combination type 4 of FIG. 42, the third transistor (T3) comprises an oxide semiconductor layer. As in the combination type 1 and the combination type 3 of FIG. 42, the third transistor (T3) comprises a silicon semiconductor layer.

As in the combination type 3 and the combination type 4 of FIG. 42, the fourth transistor (T4) comprises an oxide semiconductor layer. As in the combination type 1 and the combination type 2 of FIG. 42, the fourth transistor (T4) comprises a silicon semiconductor layer.

FIG. 40 is a schematic diagram illustrating the combination type of transistors of the pixel circuit 200 in FIG. 3 according to the present disclosure. As shown, for better performance for driving circuit, the first transistor (T1) and the second transistor (T2) comprise different semiconductor layers.

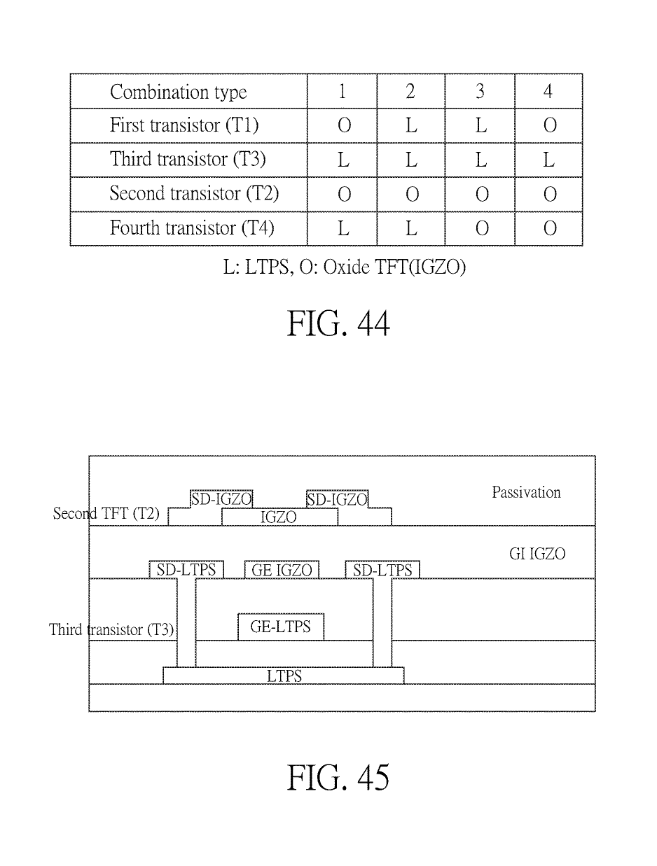

FIG. 44 is still another schematic diagram illustrating the combination type of transistors of the pixel circuit 200 in FIG. 3 according to the present disclosure. As shown, for better performance for driving circuit, the third transistor (T3) and the second transistor (T2) comprise different semiconductor layers. That is, when the third transistor (T3) is a transistor comprising the silicon semiconductor layer, the pixel circuit 200 may be improved in operation switching speed, where the silicon semiconductor layer can be a LTPS layer or amorphous silicon layer. When the second transistor (T2) is a transistor comprising the oxide semiconductor layer, the low leakage current can prevent inaccurate current flowing through the light-emitting diode (D1), where the oxide semiconductor layer can be an IGZO layer.

When the third transistor (T3) is a transistor comprising the silicon semiconductor layer and the second transistor (T2) is a transistor comprising the oxide semiconductor layer, the first transistor (T1) and the fourth transistor (T4) are each a transistor comprising the silicon semiconductor layer or a transistor comprising the oxide semiconductor layer. In the combination type 1, the first transistor (T1) comprises the oxide semiconductor layer and the fourth transistor (T4) comprises the silicon semiconductor layer. In the combination type 2, each of the first transistor (T1) and the fourth transistor (T4) comprises the silicon semiconductor layer. In the combination type 3, the first transistor (T1) comprises the silicon semiconductor layer and the fourth transistor (T4) comprises the oxide semiconductor layer. In the combination type 4, each of the first transistor (T1) and the fourth transistor (T4) comprises the oxide semiconductor layer.

In another embodiment, FIG. 45 is still another schematic diagram illustrating the gate stack-up structure of the third transistor (T3) and the second transistor (T2) in FIG. 3 according to the present disclosure. As shown in FIG. 45, the third transistor (T3) is a transistor comprising the silicon semiconductor layer and the second transistor (T2) is a transistor comprising the oxide semiconductor layer, where the silicon semiconductor layer can be a LTPS layer or amorphous silicon layer and the oxide semiconductor layer can be an IGZO layer. As shown, the first gate electrode (GE IGZO) of the second transistor (T2) is overlapped with oxide semiconductor layer. In another embodiment, when the second transistor (T2) is a dual-gate structure, the second gate electrode (not shown) of the second transistor (T2) is also overlapped with the oxide semiconductor layer. The dual-gate structure is well-known to the person skilled in the art according to the illustration of FIG. 45 of the present disclosure, and therefore is not repeated again.

As in the combination type 1 and the combination type 4 of FIG. 44, the first transistor (T1) comprises an oxide semiconductor layer. As in the combination type 2 and the combination type 3 of FIG. 44, the first transistor (T1) comprises a silicon semiconductor layer.

As in the combination type 3 and the combination type 4 of FIG. 44, the fourth transistor (T4) comprises an oxide semiconductor layer. As in the combination type 1 and the combination type 2 of FIG. 44, the fourth transistor (T4) comprises a silicon semiconductor layer.

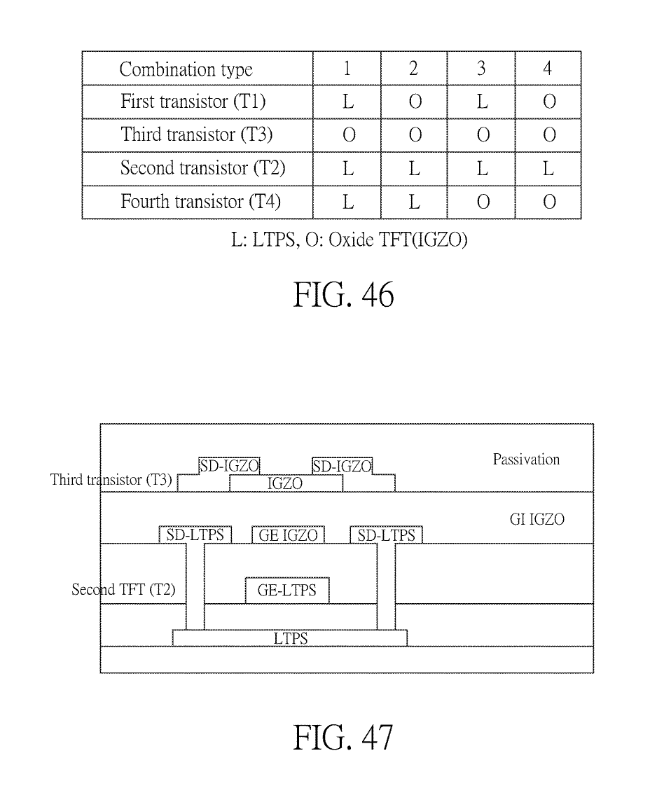

FIG. 46 is still another schematic diagram illustrating the combination type of transistors of the pixel circuit 200 in FIG. 3 according to the present disclosure. As shown, for better performance for driving circuit, the third transistor (T3) and the second transistor (T2) comprise different semiconductor layers. That is, when the third transistor (T3) is a transistor comprising the oxide semiconductor layer, the low leakage current of the third transistor (T3) can prevent wrong gate voltage of the first transistor (T1) or wrong holding voltage (of storage capacitance) from going through organic light emitting unit. When the second transistor (T2) is a transistor comprising the silicon semiconductor layer, owing to the high mobility of the silicon semiconductor layer, the pixel circuit 200 has better reset speed, where the silicon semiconductor layer can be a LTPS layer.

As shown in FIG. 46, when the third transistor (T3) is a transistor comprising the oxide semiconductor layer and the second transistor (T2) is a transistor comprising the silicon semiconductor layer, the first transistor (T1) and the fourth transistor (T4) are each a transistor comprising the silicon semiconductor layer or a transistor comprising the oxide semiconductor layer. In the combination type 1, the first transistor (T1) comprises the silicon semiconductor layer and the fourth transistor (T4) comprises the silicon semiconductor layer. In the combination type 2, the first transistor (T1) comprises the oxide semiconductor layer and the fourth transistor (T4) comprises the silicon semiconductor layer. In the combination type 3, the first transistor (T1) comprises the silicon semiconductor layer and the fourth transistor (T4) comprises the oxide semiconductor layer. In the combination type 4, each of the first transistor (T1) and the fourth transistor (T4) comprises the oxide semiconductor layer.

In another embodiment, FIG. 47 is still another schematic diagram illustrating the gate stack-up structure of the third transistor (T3) and the second transistor (T2) in FIG. 3 according to the present disclosure. As shown in FIG. 47, the third transistor (T3) is a transistor comprising the oxide semiconductor layer and the second transistor (T2) is a transistor comprising the silicon semiconductor layer, where the silicon semiconductor layer can be a LTPS layer or amorphous silicon layer and the oxide semiconductor layer can be an IGZO layer. As shown, the first gate electrode (GE LTPS) of the second transistor (T2) is overlapped with the silicon semiconductor layer. In another embodiment, when the second transistor (T2) is a dual-gate structure, the second gate electrode (not shown) of the second transistor (T2) is also overlapped with the silicon semiconductor layer. The dual-gate structure is well-known to the person skilled in the art according to the illustration of FIG. 47 of the present disclosure, and therefore is not repeated again.

As in the combination type 2 and the combination type 4 of FIG. 46, the first transistor (T1) comprises an oxide semiconductor layer. As in the combination type 1 and the combination type 3 of FIG. 46, the first transistor (T1) comprises a silicon semiconductor layer.

As in the combination type 3 and the combination type 4 of FIG. 46, the fourth transistor (T4) comprises an oxide semiconductor layer. As in the combination type 1 and the combination type 2 of FIG. 46, the fourth transistor (T4) comprises a silicon semiconductor layer.

It is noted that, in the present disclosure, a symbol may represent a signal name or a voltage of the signal. For example, the symbol “Vini” may represent an initial signal or a voltage of the initial signal.

From the aforementioned descriptions, the fourth transistor can be a transistor comprising a silicon semiconductor layer such that the fourth transistor may have better electron mobility and stability. The transistor comprising a silicon semiconductor layer can provide a larger current and a larger driving capability in its turn-on state for driving the light-emitting diode. The first transistor of the pixel circuit can be a transistor comprising an oxide semiconductor layer for providing low threshold voltage variation of the first transistor, such that the first transistor may have better threshold voltage uniformity. The first transistor can thus provide a much more uniformed current to drive the OLED, solving problems of mura or poor brightness uniformity. Moreover, in the present disclosure, it also provides a commonly-shared gate stack-up structure which can dramatically reduce the layout area.

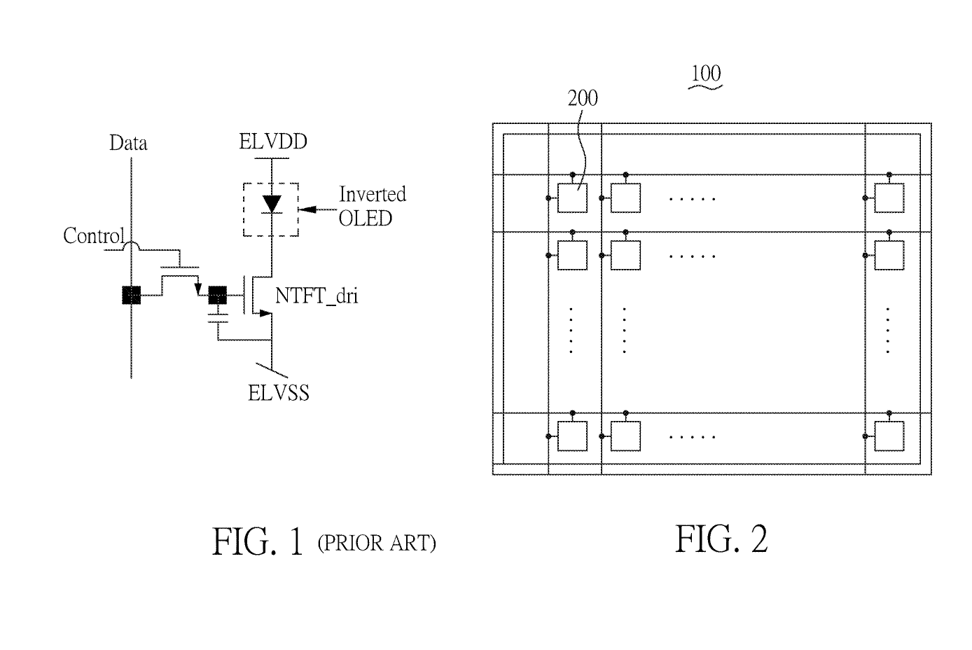

In another embodiment, FIG. 2 is a schematic diagram of a display panel according to the present disclosure. The display panel 100 is an light-emitting diode display panel having a plurality of pixel circuits 200 of active-matrix light-emitting diode, where the light emitting diode (D1) can be an organic light emitting diode or a LED chip. Each of the pixel circuits 200 is used to drive a corresponding device for display. FIG. 3 is a circuit diagram of a pixel circuit 200 of active-matrix light-emitting diode according to a first embodiment of the present disclosure. As shown in FIG. 3, the pixel circuit 200 includes a third transistor (T3), a first transistor (T1), a first storage capacitor (Cst), a fourth transistor (T4), a second storage capacitor (C1), and a second transistor (T2). The pixel circuit 200 is used to drive a light-emitting diode (D1).

The third transistor (T3) has a second control terminal (c1) connected to a first control signal (Sn), a fourth terminal (a1) connected to a data line (Data), and a fifth terminal (b1). The first transistor (T1) has a first control terminal (c2) connected to the fifth terminal (b1), a second terminal (a2), and a third terminal (b2). The first storage capacitor (Cst) is connected to the first control terminal (c2) and the third terminal (b2).

The fourth transistor (T4) has a third control terminal (c3) connected to a second control signal (En), a sixth terminal (a3) connected to a high voltage (ELVDD), and a seventh terminal (b3) connected to the second terminal (a2). The second storage capacitor (C1) is connected to the sixth terminal (a3) and the third terminal (b2), and the second storage capacitor (C1) is electrically connected to the light emitting diode (D1) via the third terminal (b2). The second transistor (T2) has a fourth control terminal (c4) connected to a reset signal (RST), an eighth terminal (a4) connected to an initial signal (Vini), and a ninth terminal (b4) connected to the third terminal (b2).

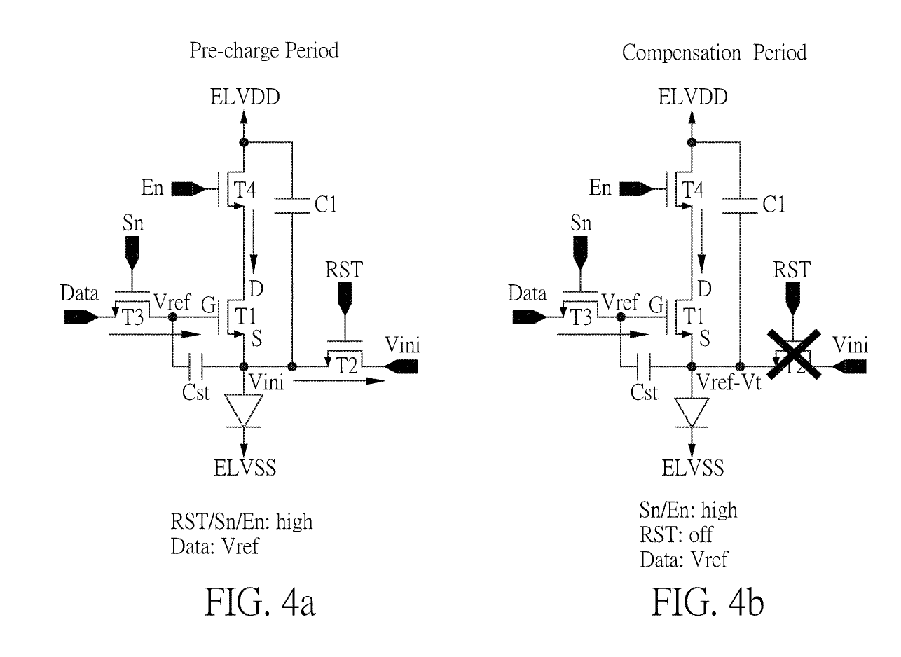

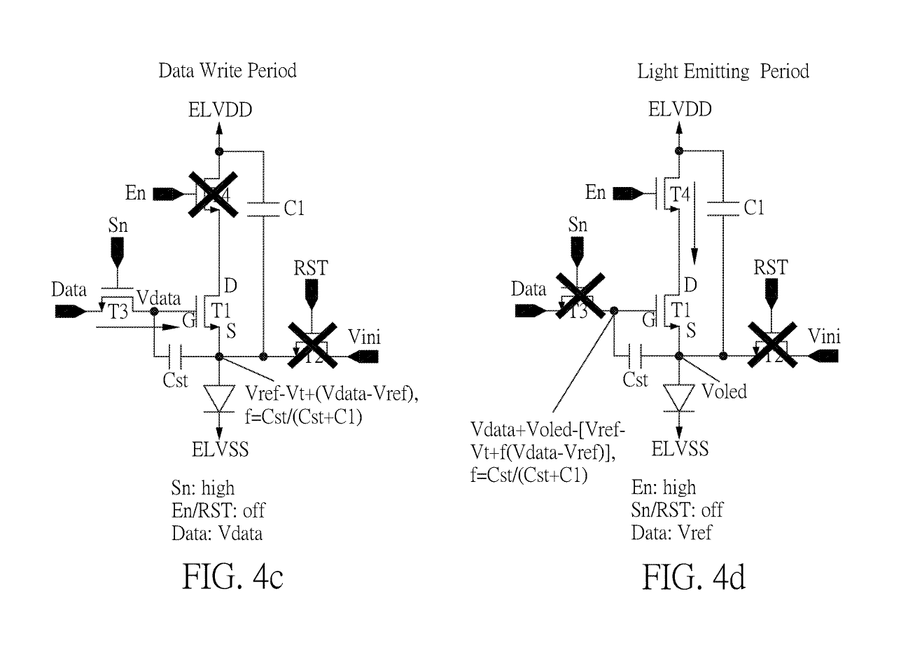

FIG. 4a to FIG. 4d are schematic diagrams illustrating the operation of the pixel circuit 200 of FIG. 3 according to the present disclosure. As shown in FIG. 4a, in a pre-charge period, the reset signal (RST) is a high control voltage (VDD), the first control signal (Sn) is a high control voltage (VDD), the second control signal (En) is a high control voltage (VDD), and the voltage of the data line (Data) is a reference voltage (Vref).

The voltage level of the high control voltage (VDD) can be equal to or different from that of the high voltage (PLVDD).

As shown in FIG. 4a, in the pre-charge period, the third transistor (T3), the first transistor (T1), the fourth transistor (T4), and the second transistor (T2) are turned on, and the voltage of the data line (Data) is the reference voltage (Vref). Therefore, the voltage of node G is the reference voltage (Vref) and the voltage of node S is the voltage of the initial signal (Vini). It is noted that, in the figures of the present disclosure, a label, such as Vini, may represent a signal or a voltage of the signal.

In a compensation period, the first control signal (Sn) is the high control voltage (VDD), the second control signal (En) is the high control voltage (VDD), the reset signal (RST) is a low control voltage (VSS), and the voltage of the data line (Data) is the reference voltage (Vref). Similarly, the voltage level of the low control voltage (VSS) can be equal to or different from that of the low voltage (PLVSS).

As shown in FIG. 4b, in the compensation period, the third transistor (T3), the first transistor (T1) and the fourth transistor (T4) are turned on, the second transistor (T2) is turned off, and the voltage of the data line (Data) is the reference voltage (Vref). Therefore, the voltage of node G is the reference voltage (Vref) and the voltage of node S is equal to Vref−Vt, where Vref is the voltage of the reference signal, and Vt is the threshold voltage of the first transistor (T1).

In a data writing period, the reset signal (RST) is the low control voltage (VSS), the first control signal (Sn) is the high control voltage (VDD), the second control signal (En) is the low control voltage (VSS), and the voltage of the data line (Data) is a data write voltage (Vdata).

As shown in FIG. 4c, in the data writing period, the third transistor (T3) and the first transistor (T1) are turned on, the fourth transistor (T4) and the second transistor (T2) are turned off, and the voltage of the data line (Data) is the data write voltage (Vdata). Therefore, the voltage of node G is the data write voltage (Vdata) and the voltage of node S is equal to Vref−Vt+f×(Vdata−Vref), where Vdata is the voltage of the data write voltage (Vdata), f is equal to Cst/(Cst+C1), Cst is the capacitance of the first storage capacitor (Cst), and C1 is the capacitance of the second storage capacitor (C1).

In a light emitting period, the reset signal (RST) is the low control voltage (VSS), the first control signal (Sn) is the low control voltage (VSS), and the second control signal (En) is the high control voltage (VDD).

As shown in FIG. 4d, in the light emitting period, the fourth transistor (T4) and the first transistor (T1) are turned on, and the third transistor (T3) and the second transistor (T2) are turned off. Therefore, the voltage of node G is equal to Vdata+V−[Vref−Vt+f×(Vdata−Vref)] and the voltage of node S is equal to V, where V is the voltage of anode of the light emitting diode (D1). Owing to the voltage of node G being equal to the threshold voltage (Vt), in the light emitting period, it can compensate the threshold voltage variation resulted from the polycrystalline process and thus compensate the voltage across the light emitting diode (D1) for mitigating mura or poor brightness uniformity.

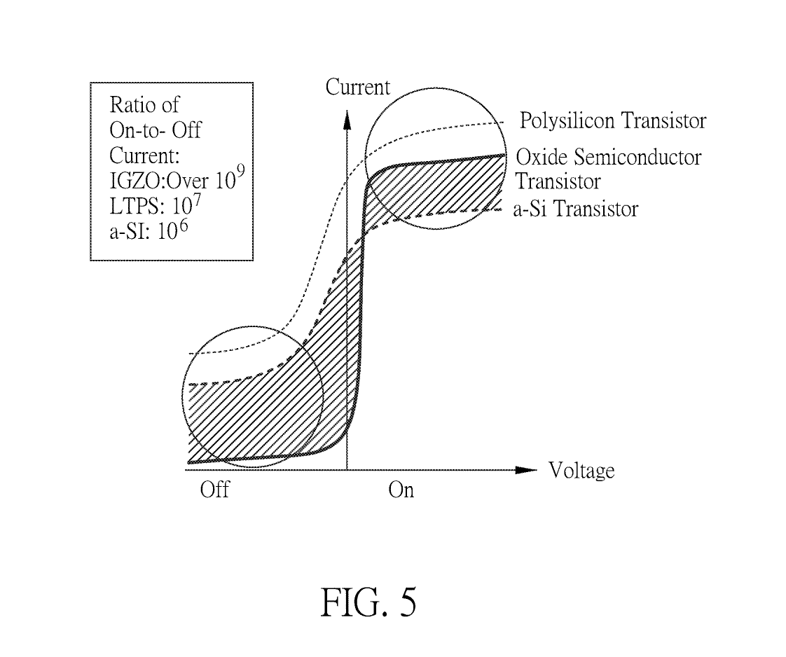

FIG. 5 schematically illustrates currents of the polysilicon transistor, the oxide semiconductor transistor, and the amorphous silicon (a-Si) transistor. As shown, the polysilicon transistor has a large current in the turn-on state. The oxide semiconductor transistor has a low leakage current in the turn-off state. The leakage current of the oxide semiconductor layer is much smaller than that of the polysilicon transistor or the a-Si transistor. In one embodiment of the present disclosure, the threshold voltage (Vt) of the first transistor (T1) needs to have better uniformity and the third transistor (T3) requires low leakage current, and thus the first transistor (T1) or the third transistor (T3) is such a transistor comprising an oxide semiconductor layer, where the oxide semiconductor layer can be an indium gallium zinc oxide (IGZO) layer. The fourth transistor (T4) needs to have better electron mobility and stability, and thus the fourth transistor (T4) is such a transistor comprising a polysilicon semiconductor layer, where the polysilicon semiconductor layer can be a low temperature poly-silicon (LTPS) layer. The second transistor (T2) is such a transistor comprising a polysilicon semiconductor layer for reducing circuit layout area.

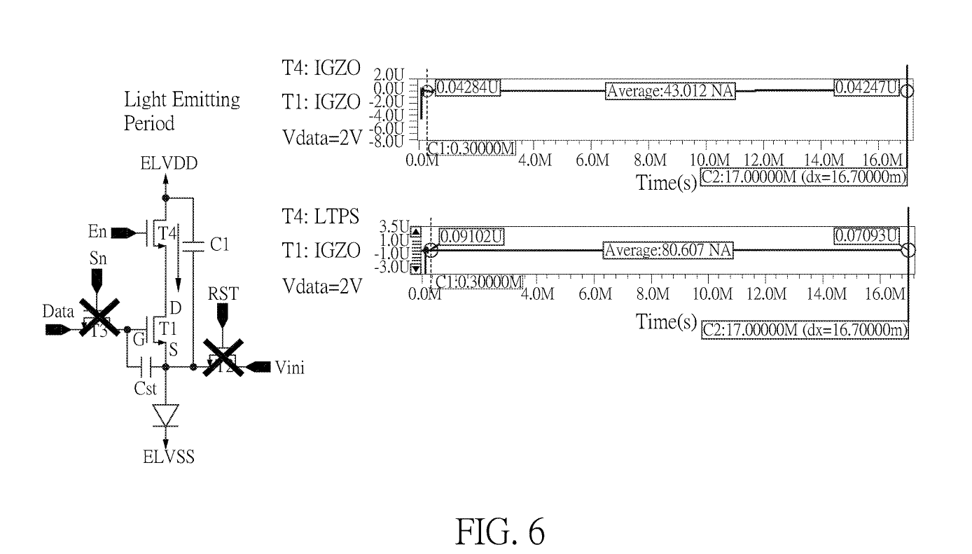

FIG. 6 schematically illustrates a simulation result for the pixel circuit 200 of FIG. 3 according to the present disclosure. It simulates the currents of the fourth transistor (T4) and the first transistor (T1) of the pixel circuit 200 in the light emitting period. In the upper-half of FIG. 6, it illustrates the currents of the fourth transistor (T4) and the first transistor (T1), each comprising an oxide semiconductor layer. In the bottom-half of FIG. 6, it illustrates the currents of the fourth transistor (T4) and the first transistor (T1), each comprising a polysilicon semiconductor layer.

In the light emitting period, the current of the first transistor (T1) controls the amount of current of the light emitting diode (D1), and the fourth transistor (T4) controls the light emitting period of the light emitting diode (D1). Thus, it needs to ensure that the current of the fourth transistor (T4) is larger than that of the first transistor (T1). As shown in FIG. 6, when the fourth transistor (T4) is a transistor comprising the polysilicon semiconductor layer, the current of the fourth transistor (T4) is 80 nA. When the fourth transistor (T4) is a transistor comprising the oxide semiconductor layer, the current of the fourth transistor (T4) is 43 nA. Because of requiring better electron mobility and stability, the fourth transistor (T4) is a transistor comprising the polysilicon semiconductor layer. Moreover, because the threshold voltage (Vt) of the first transistor (T1) requires better uniformity, the first transistor (T1) is a transistor comprising the oxide semiconductor layer.

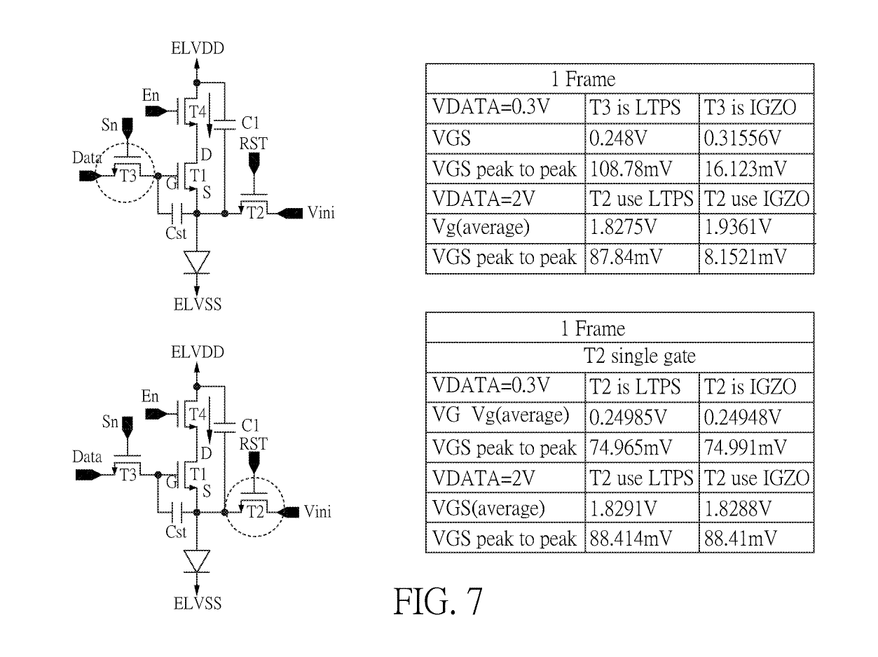

FIG. 7 schematically illustrates another simulation result for the pixel circuit 200 of FIG. 3 according to the present disclosure. It simulates the currents of the third transistor (T3) and the second transistor (T2) of the pixel circuit 200 for selecting the transistor types of the third transistor (T3) and the second transistor (T2). In FIG. 7, VGS represents the voltage between the gate and the source of the first transistor (T1), and VGS peak to peak represents the difference of VGS of each display frame. As shown, when Vdata is 0.3 V and the third transistor (T3) is a transistor comprising the polysilicon semiconductor layer, VGS peak to peak is equal to 108.78 mV. When the third transistor (T3) is a transistor comprising the oxide semiconductor layer, VGS peak to peak is equal to 16.123 mV. When Vdata is 2 V and the third transistor (T3) is a transistor comprising the polysilicon semiconductor layer, VGS peak to peak is equal to 87.84 mV. When the third transistor (T3) is a transistor comprising the oxide semiconductor layer, VGS peak to peak is equal to 8.1521 mV. Thus, it is known that, when the third transistor (T3) is a transistor comprising the oxide semiconductor layer, VGS peak to peak is provided with a better stability.

Moreover, as shown in FIG. 7, there is not much influence to VGS peak to peak when the second transistor (T2) is a transistor comprising the polysilicon semiconductor layer or the oxide semiconductor layer.

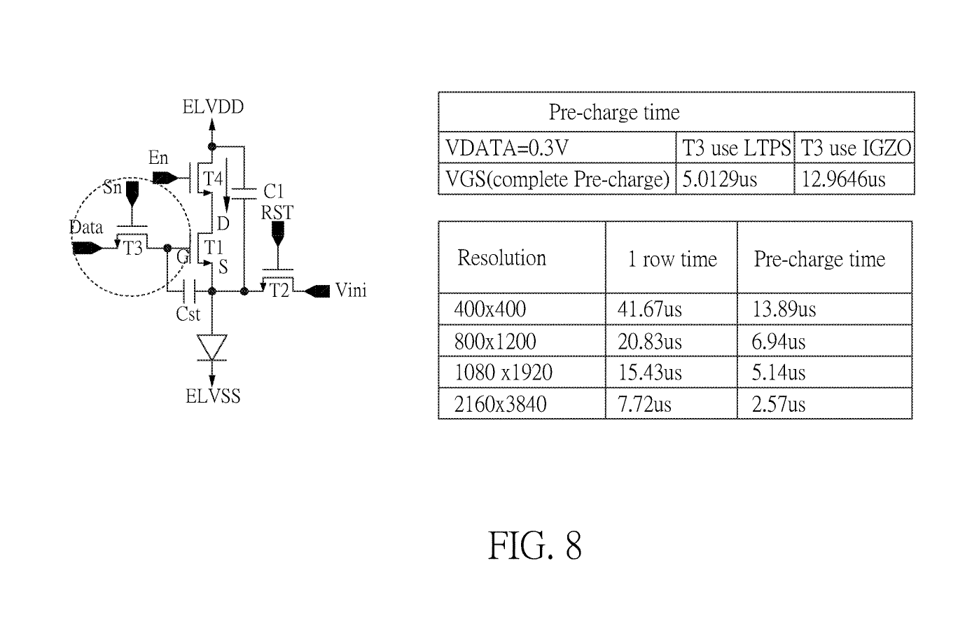

FIG. 8 schematically illustrates still another simulation result for the pixel circuit 200 of FIG. 3 according to the present disclosure. It simulates the pre-charge time of the third transistor (T3) of the pixel circuit 200 for selecting the transistor type of the third transistor (T3). As shown in FIG. 8, when Vdata is 0.3 V and the third transistor (T3) is a transistor comprising the polysilicon semiconductor layer, the pre-charge time is equal to 5.0129 μs. When the third transistor (T3) is a transistor comprising the oxide semiconductor layer, the pre-charge time is equal to 12.9646 μs. Thus, in another embodiment of the present disclosure, the first transistor (T1) can be a transistor comprising an oxide semiconductor layer. Because of requiring better electron mobility and stability, the fourth transistor (T4) is a transistor comprising the polysilicon semiconductor layer. The second transistor (T2) can be a transistor comprising the polysilicon semiconductor layer for reducing circuit layout area, and the third transistor (T3) can be a transistor comprising the polysilicon semiconductor layer for reducing the pre-charge time.

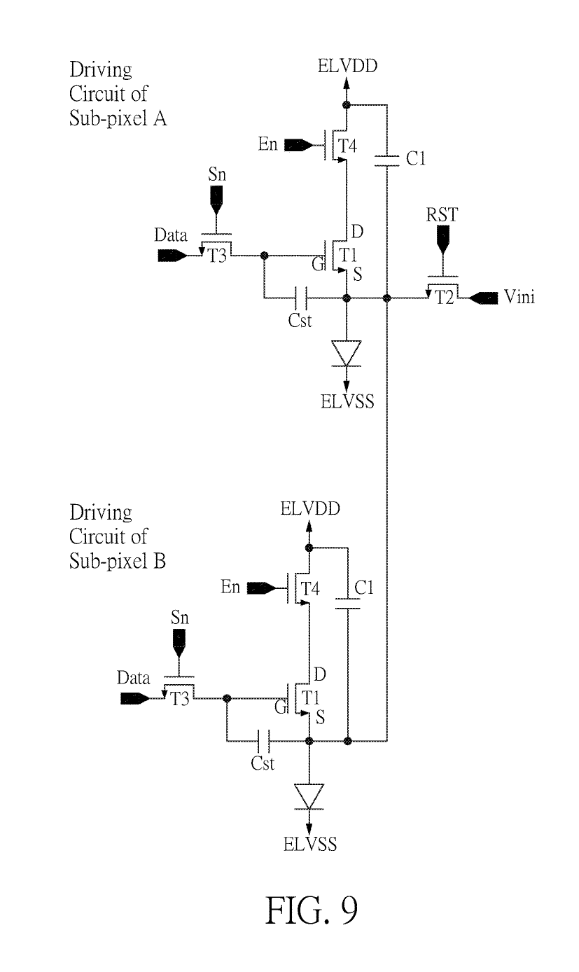

FIG. 9 is a schematic view illustrating an application of the pixel circuit 200 of FIG. 3 according to the present disclosure. As shown, the second transistor (T2) is shared between two pixel circuits 200. That is, the second transistor (T2) of the pixel circuit 200 of one sub-pixel (A) can be shared with the pixel circuit 200 of another sub-pixel (B). The hardware structure of the pixel circuit 200 of the sub-pixel (A) is the same as that of the pixel circuit 200 of the sub-pixel (B), and the second transistor (T2) is a transistor comprising the oxide semiconductor layer. With the sharing of the second transistor (T2) between the pixel circuit 200 of the sub-pixel (A) and the pixel circuit 200 of the sub-pixel (B), it can dramatically reduce the number of transistors in an application. For example, in a full high definition (FHD) display panel, the display panel has 6,220,800 (=1080×1920×3) sub-pixels and thus there are 6,220,800 pixel circuits 200. With the sharing technology of the present disclosure, there is one transistor saved for two pixel circuits 200. Therefore, in a full high definition (FHD) display panel, it can save 3,110,400 transistors.

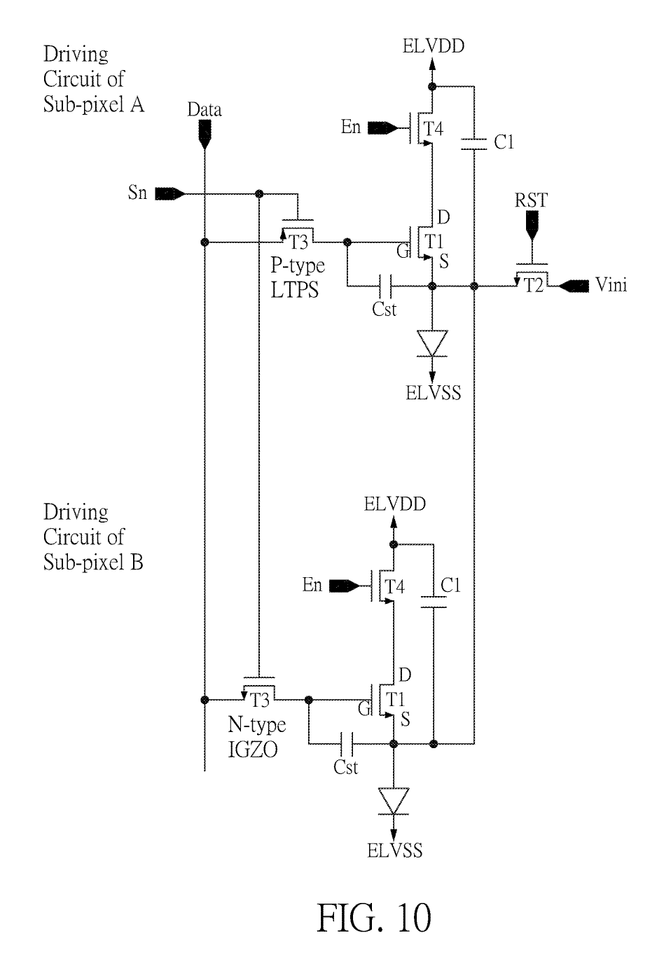

FIG. 10 is a schematic view illustrating another application of the pixel circuit 200 of FIG. 3 according to the present disclosure. As shown, the second transistor (T2) of the pixel circuit 200 of the sub-pixel (A) is shared with the pixel circuit 200 of another sub-pixel (B). The hardware structure of the pixel circuit 200 of the sub-pixel (A) is the same as that of the pixel circuit 200 of the sub-pixel (B). As shown in FIG. 10, the third transistor (T3) of the pixel circuit 200 of the sub-pixel (A) is a transistor comprising a P-type polysilicon semiconductor layer and the third transistor (T3) of the pixel circuit 200 of the sub-pixel (B) is a transistor comprising an N-type oxide semiconductor layer. The third transistor (T3) of the sub-pixel (A) and the third transistor (T3) of the sub-pixel (B) are controlled by the same first control signal (Sn). The fourth transistor (T4) of the sub-pixel (A) or the fourth transistor (T4) of the sub-pixel (B) can be a transistor comprising the P-type polysilicon semiconductor layer or the N-type polysilicon semiconductor layer. In another embodiment, in consideration of driving capability, the fourth transistor (T4) of the sub-pixel (A) or the fourth transistor (T4) of the sub-pixel (B) can be a transistor comprising the P-type polysilicon semiconductor layer.

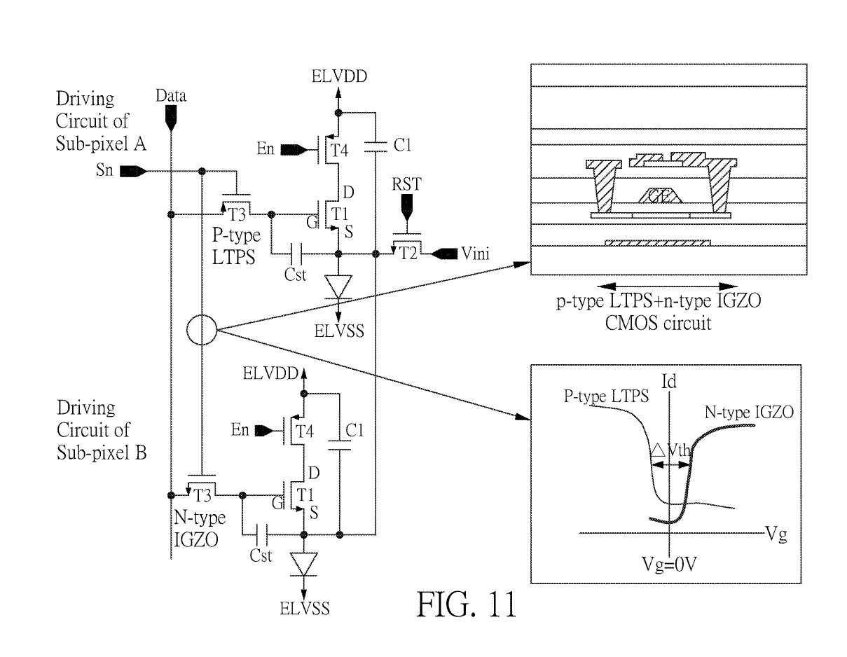

FIG. 11 is a schematic view illustrating still another application of the pixel circuit 200 of FIG. 3 according to the present disclosure. As shown, the second transistor (T2) of the pixel circuit 200 of one sub-pixel (A) is shared with the pixel circuit 200 of another sub-pixel (B). The hardware structure of the pixel circuit 200 of the sub-pixel (A) is the same as that of the pixel circuit 200 of the sub-pixel (B). As shown in FIG. 11, the fourth transistor (T4) of the sub-pixel (A) or the fourth transistor (T4) of the sub-pixel (B) is a transistor comprising the P-type polysilicon semiconductor layer, and the first transistor (T1) of the sub-pixel (A) or the first transistor (T1) of the sub-pixel (B) is a transistor comprising the N-type oxide semiconductor layer.

As shown in FIG. 11, each of the fourth transistors (T4) of the sub-pixel (A) and the sub-pixel (B) is a transistor comprising the P-type polysilicon semiconductor layer, and each of the first transistors (T1) of the sub-pixel (A) and the sub-pixel (B) is a transistor comprising the N-type oxide semiconductor layer. The third transistor (T3) of the pixel circuit 200 of the sub-pixel (A) is a transistor comprising the P-type polysilicon semiconductor layer and the third transistor (T3) of the pixel circuit 200 of the sub-pixel (B) is a transistor comprising the N-type oxide semiconductor layer. The third transistor (T3) of the pixel circuit 200 of the sub-pixel (A) and the third transistor (T3) of the pixel circuit 200 of the sub-pixel (B) are controlled by the same first control signal (Sn).

As shown in FIG. 11, the third transistor (T3) of the pixel circuit 200 of the sub-pixel (A) is provided with a bottom gate structure and the third transistor (T3) of the pixel circuit 200 of the sub-pixel (B) is provided with a top gate structure. The third transistor (T3) of the pixel circuit 200 of the sub-pixel (A) and the third transistor (T3) of the pixel circuit 200 of the sub-pixel (B) share a common gate. With the commonly-shared gate of the third transistor (T3) of the sub-pixel (A) and the third transistor (T3) of the sub-pixel (B), the third transistor (T3) of the sub-pixel (A) and the third transistor (T3) of the sub-pixel (B) have a stack-up structure in circuit layout, which can dramatically reduce the layout area.

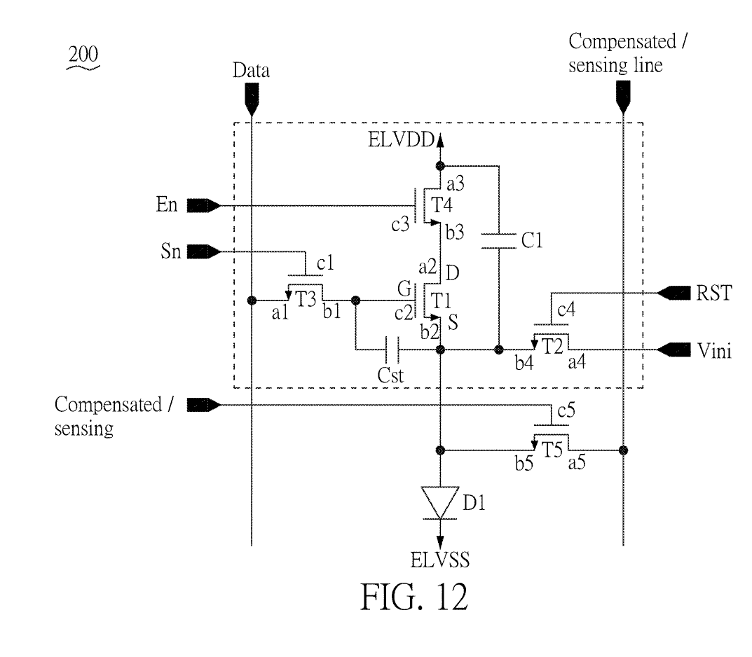

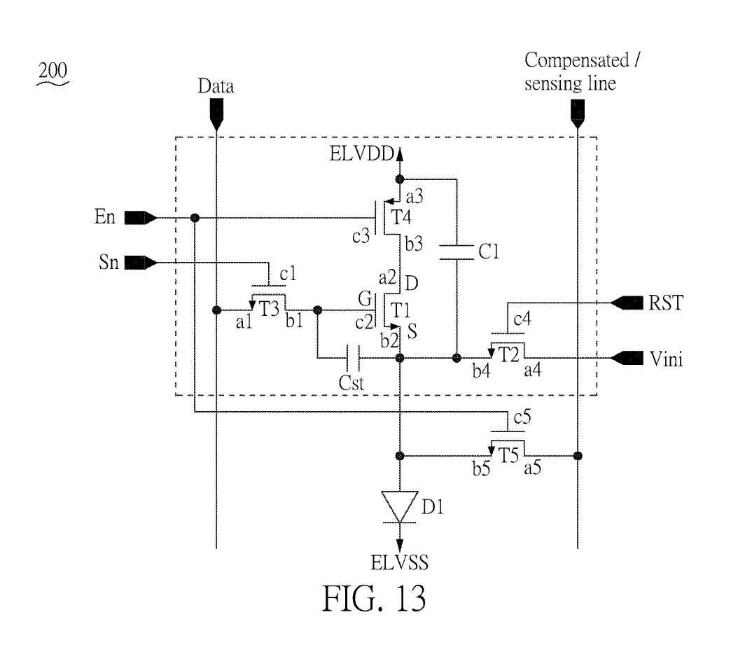

FIG. 12 is a circuit diagram of active-matrix light-emitting diode according to a second embodiment of the present disclosure. In comparison with FIG. 3, the pixel circuit 200 in FIG. 12 further comprises a fifth transistor (T5). The fifth transistor (T5) has a fifth control terminal (c5) connected to a compensated/sensing signal, a tenth terminal (a5) connected to a compensated/sensing line, and an eleventh terminal (b5) connected to the third terminal (b2). The connection for the remaining components is similar to that for FIG. 3, and therefore is not repeated again.

As shown in FIG. 12, the fourth transistor (T4) is a transistor comprising a polysilicon semiconductor layer, the first transistor (T1) is a transistor comprising an oxide semiconductor layer, and the third transistor (T3), the second transistor (T2) and the fifth transistor (T5) are each a transistor comprising the polysilicon semiconductor layer or a transistor comprising the oxide semiconductor layer.

FIG. 13 is schematic view illustrating an application of the pixel circuit 200 of FIG. 12 according to the present disclosure, which is similar to FIG. 12 except that, in FIG. 13, the compensated/sensing signal of the pixel circuit 200 is removed, and the fifth control terminal (c5) is connected to the second control signal (En). In this example, the fourth transistor (T4) is a P-type transistor, and the fifth transistor (T5) is an N-type transistor.

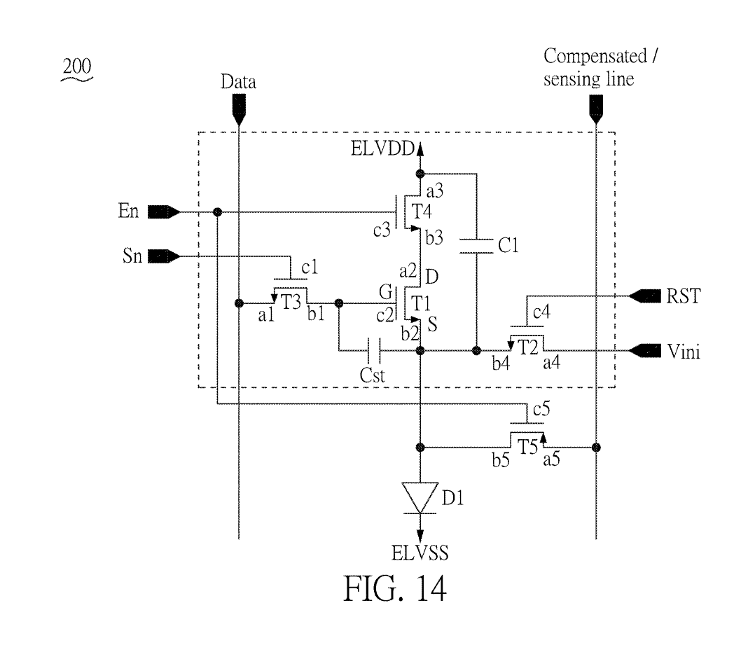

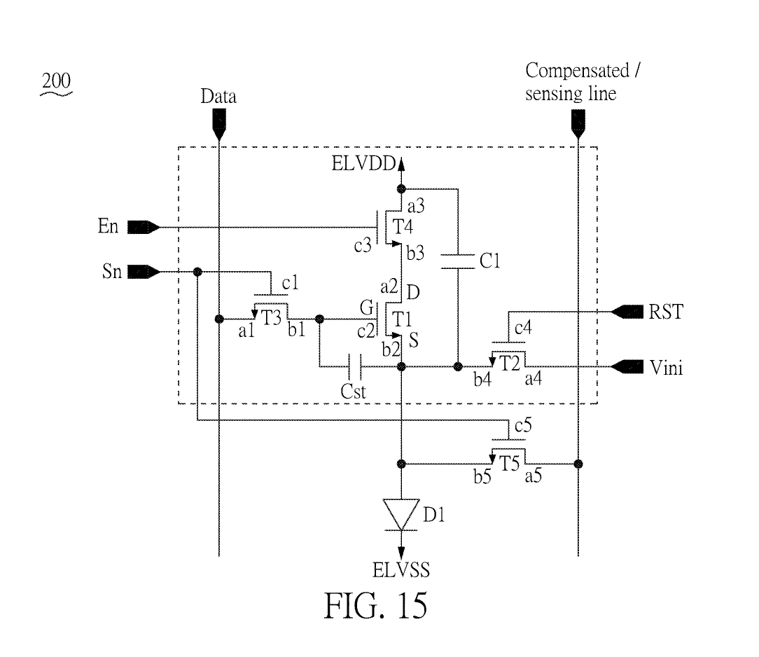

FIG. 14 is schematic view illustrating another application of the pixel circuit 200 of FIG. 12 according to the present disclosure, which is similar to FIG. 12 except that, in FIG. 14, the compensated/sensing signal of the pixel circuit 200 is removed, and the fifth control terminal (c5) is connected to the second control signal (En). In this example, the fourth transistor (T4) is an N-type transistor, and the fifth transistor (T5) is a P-type transistor.

FIG. 15 is schematic view illustrating still another application of the pixel circuit 200 of FIG. 12 according to the present disclosure, which is similar to FIG. 12 except that, in FIG. 15, the compensated/sensing signal of the pixel circuit 200 is removed, and the fifth control terminal (c5) is connected to the first control signal (Sn).

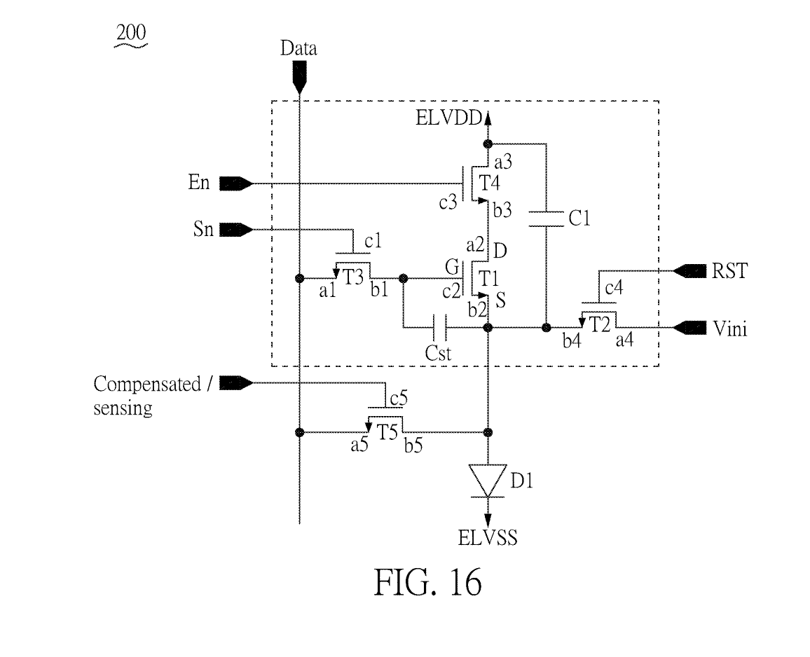

FIG. 16 is a circuit diagram of a pixel circuit 200 of active-matrix light-emitting diode according to a third embodiment of the present disclosure. In comparison with FIG. 12, the fifth transistor (T5) in FIG. 16 has a fifth control terminal (c5) connected to the compensated/sensing signal, a tenth terminal (a5) connected to the data line (Data), and an eleventh terminal (b5) connected to the third terminal (b2). The connection for the remaining components is similar to that for FIG. 12, and therefore is not repeated again.

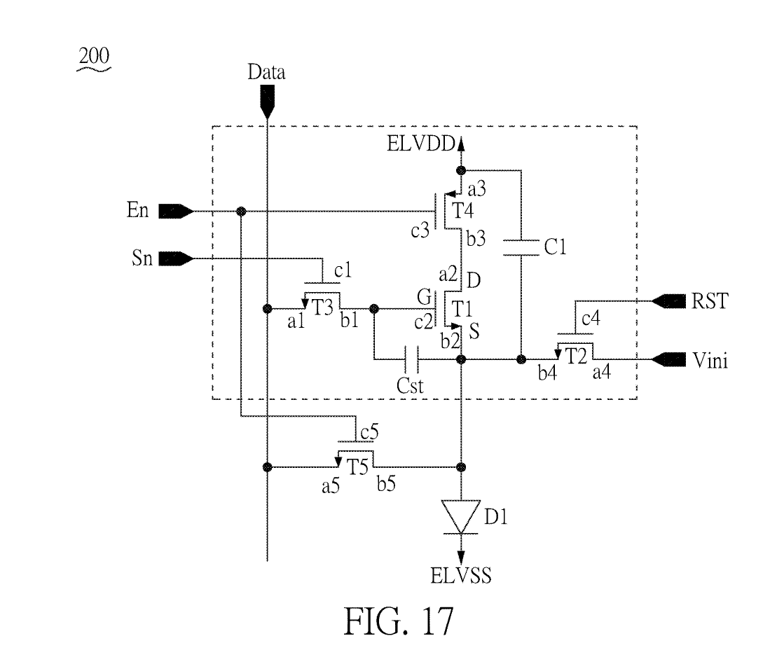

FIG. 17 is schematic view illustrating an application of the pixel circuit 200 of FIG. 16 according to the present disclosure, which is similar to FIG. 16 except that, in FIG. 17, the compensated/sensing signal of the pixel circuit 200 is removed, and the fifth control terminal (c5) is connected to the second control signal (En). In this example, the fourth transistor (T4) is a P-type transistor, and the fifth transistor (T5) is an N-type transistor.

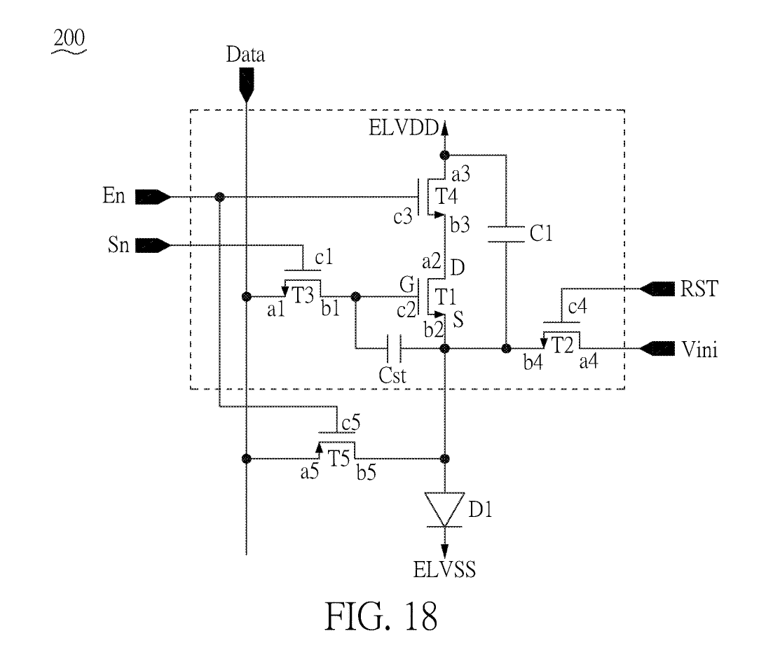

FIG. 18 is schematic view illustrating another application of the pixel circuit 200 of FIG. 16 according to the present disclosure, which is similar to FIG. 16 except that, in FIG. 18, the compensated/sensing signal of the pixel circuit 200 is removed, and the fifth control terminal (c5) is connected to the second control signal (En). In this example, the fourth transistor (T4) is an N-type transistor, and the fifth transistor (T5) is a P-type transistor.

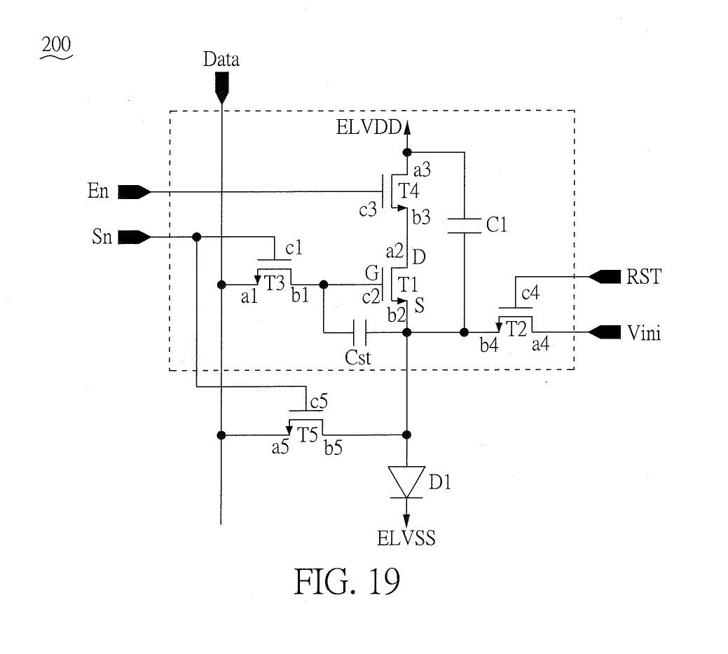

FIG. 19 is schematic view illustrating still another application of the pixel circuit 200 of FIG. 16 according to the present disclosure, which is similar to FIG. 16 except that, in FIG. 19, the compensated/sensing signal of the pixel circuit 200 is removed, and the fifth control terminal (c5) is connected to the first control signal (Sn).

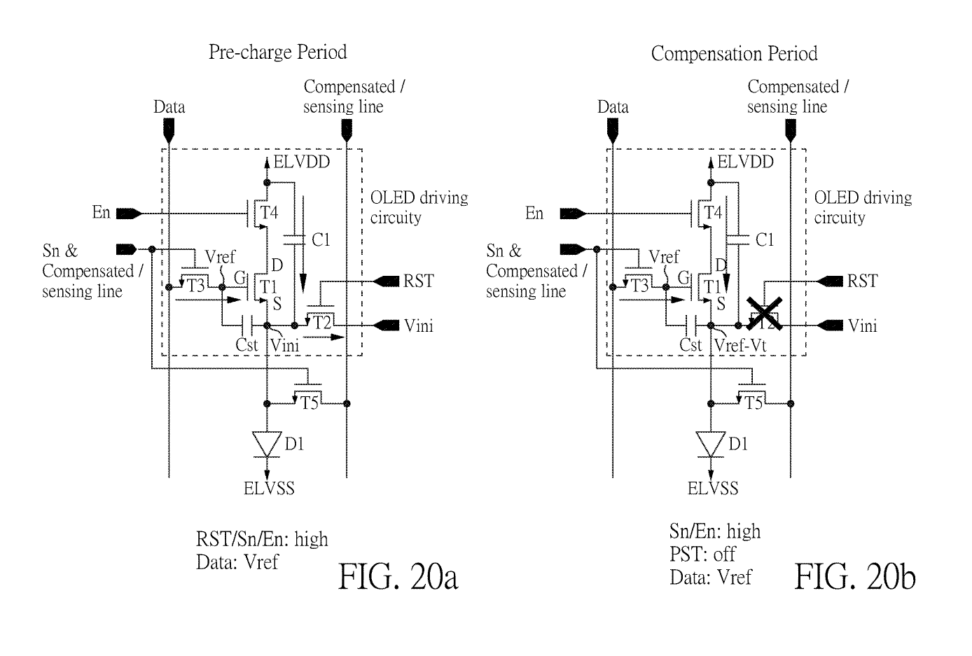

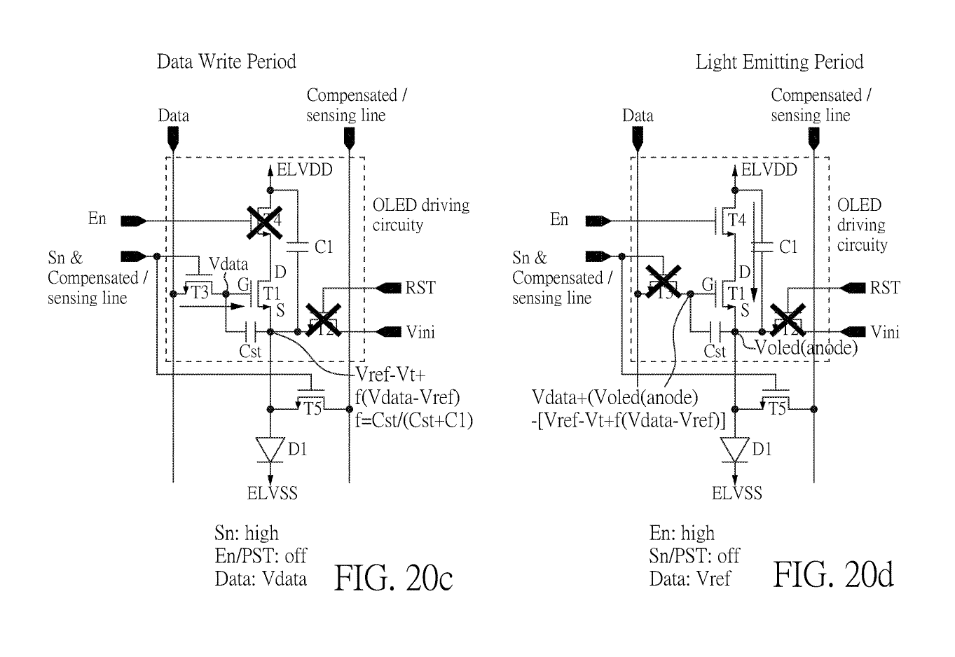

FIG. 20a to FIG. 20d are schematic diagrams illustrating the operation of the pixel circuit 200 of FIG. 15 according to the present disclosure. The operation theory and the voltage of each node are similar to FIG. 4a to FIG. 4d, and therefore is not repeated again.

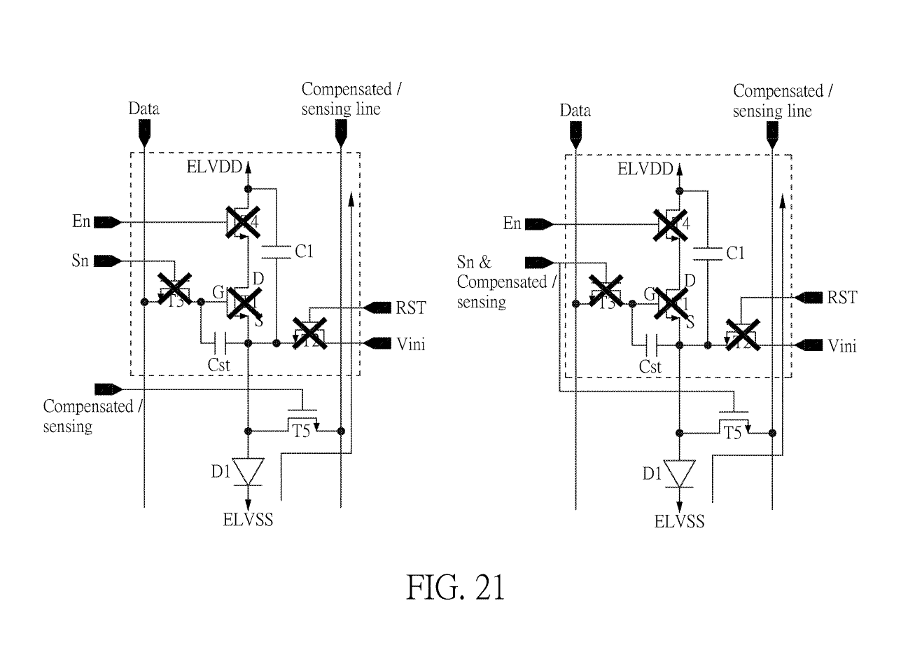

The fifth transistor (T5) is provided to compensate the current of the light emitting diode (D1). The current compensation is not performed in the pre-charge period, the compensation period, the data writing period, or the light emitting period shown in FIG. 20a to FIG. 20d. In contrast, in the panel booting process, the fifth transistor (T5) compensates the current of the light emitting diode (D1). FIG. 21 is a schematic view illustrating current compensation for the light emitting diode (D1) according to the present disclosure, in which the pixel circuits of FIG. 12 and FIG. 15 are taken as examples. In the panel booting process, the first transistor (T1), the third transistor (T3), the second transistor (T2), and the fourth transistor (T4) are turned off, and the fifth transistor (T5) is turned on. At this moment, an external sensing device (not shown) can sense the current of the light emitting diode (D1), so as to determine the magnitude of the compensation current and calculate the corresponding gate-source voltage (Vgs5) of the fifth transistor (T5). In compensation, the gate-source voltage (Vgs5) is applied to the fifth control terminal (c5) of the fifth transistor (T5) by the compensated/sensing signal for compensating the current of the light emitting diode (D1). The current compensation technology shown in FIG. 21 is applied to the pixel circuit 200 of FIG. 12 and FIG. 15. The current compensation technology for other pixel circuits is similar to that for FIG. 12 and FIG. 15, and therefore is not repeated again.

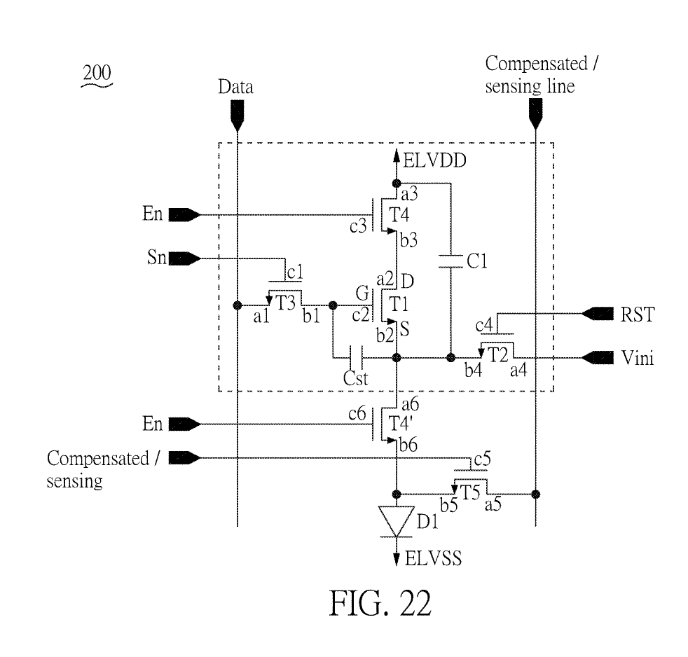

FIG. 22 is a circuit diagram of a pixel circuit 200 of active-matrix light-emitting diode according to a fourth embodiment of the present disclosure. In comparison with FIG. 3, the pixel circuit 200 in FIG. 22 further comprises a fifth transistor (T5) and a transistor (T4′). The fifth transistor (T5) has a fifth control terminal (c5) connected to a compensated/sensing signal, a tenth terminal (a5) connected to a compensated/sensing line, and an eleventh terminal (b5) connected to the light emitting diode (D1). The transistor (T4′) has a sixth control terminal (c6) connected to the second control signal (En), an twelfth terminal (a6) connected to the third terminal (b2), a thirteenth terminal (b6) connected to the eleventh terminal (b5) and the light emitting diode (D1). The connection for the remaining components is similar to that for FIG. 3, and therefore is not repeated again.

As shown in FIG. 22, the fourth transistor (T4) and the transistor (T4′) are each a transistor comprising the polysilicon semiconductor layer. The first transistor (T1) is a transistor comprising an oxide semiconductor layer. The third transistor (T3), the second transistor (T2) and the fifth transistor (T5) are each a transistor comprising the polysilicon semiconductor layer or a transistor comprising the oxide semiconductor layer.

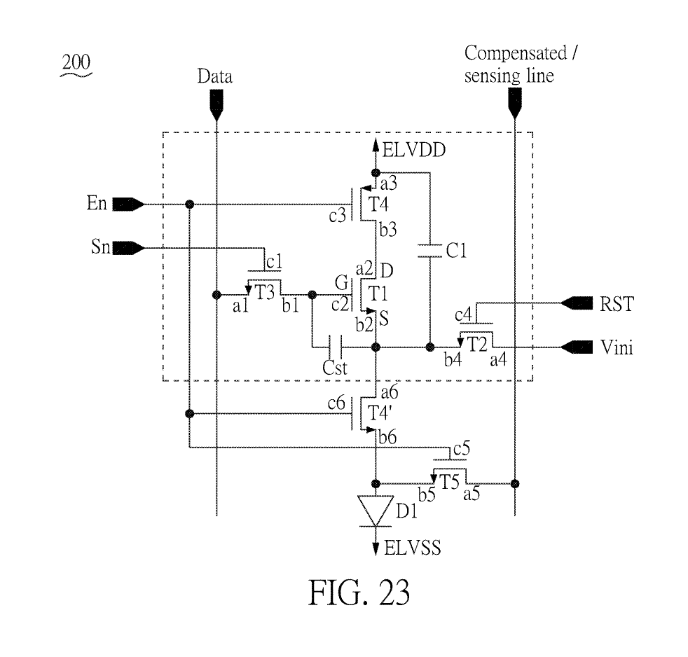

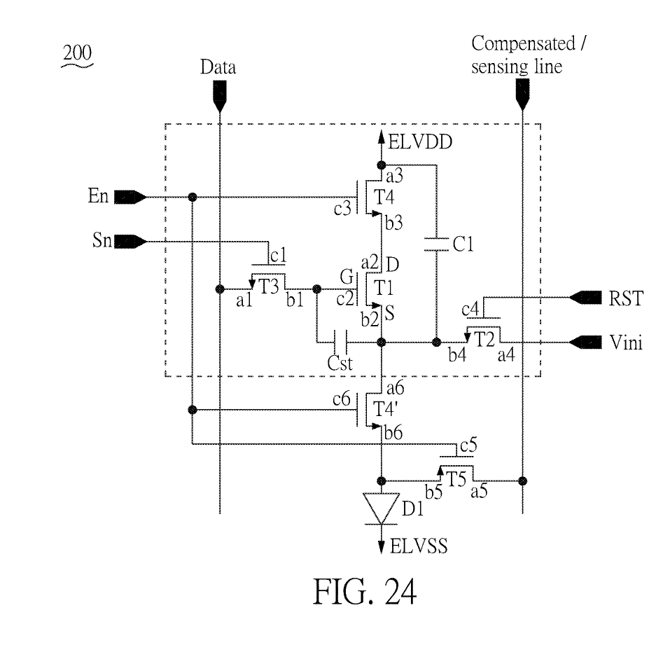

FIG. 23 is schematic view illustrating an application of the pixel circuit 200 of FIG. 22 according to the present disclosure, which is similar to FIG. 22 except that, in FIG. 23, the compensated/sensing signal of the pixel circuit 200 is removed, and the fifth control terminal (c5) is connected to the second control signal (En). In this example, the fourth transistor (T4) is a P-type transistor, and the fifth transistor (T5) is an N-type transistor.

FIG. 24 is schematic view illustrating another application of the pixel circuit 200 of FIG. 22 according to the present disclosure, which is similar to FIG. 22 except that, in FIG. 24, the compensated/sensing signal of the pixel circuit 200 is removed, and the fifth control terminal (c5) is connected to the second control signal (En). In this example, the fourth transistor (T4) is an N-type transistor, and the fifth transistor (T5) is a P-type transistor.

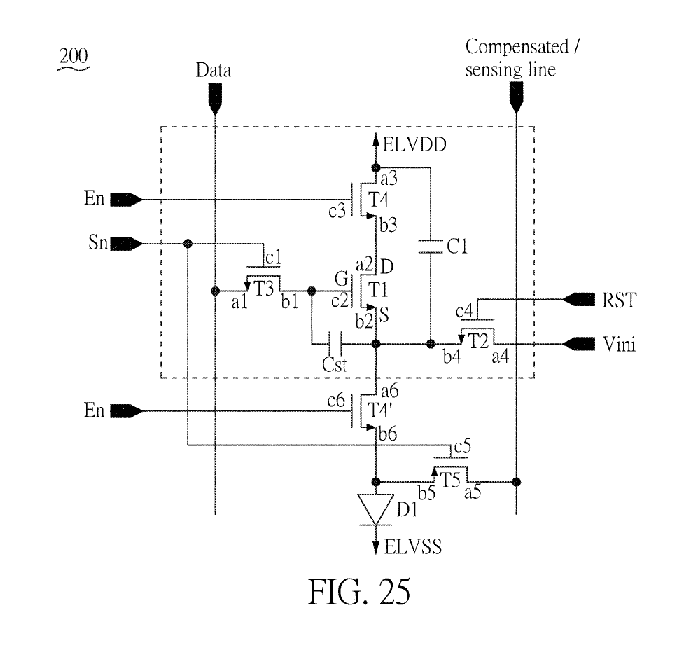

FIG. 25 is schematic view illustrating still another application of the pixel circuit 200 of FIG. 22 according to the present disclosure, which is similar to FIG. 22 except that, in FIG. 25, the compensated/sensing signal of the pixel circuit 200 is removed, and the fifth control terminal (c5) is connected to the first control signal (Sn).

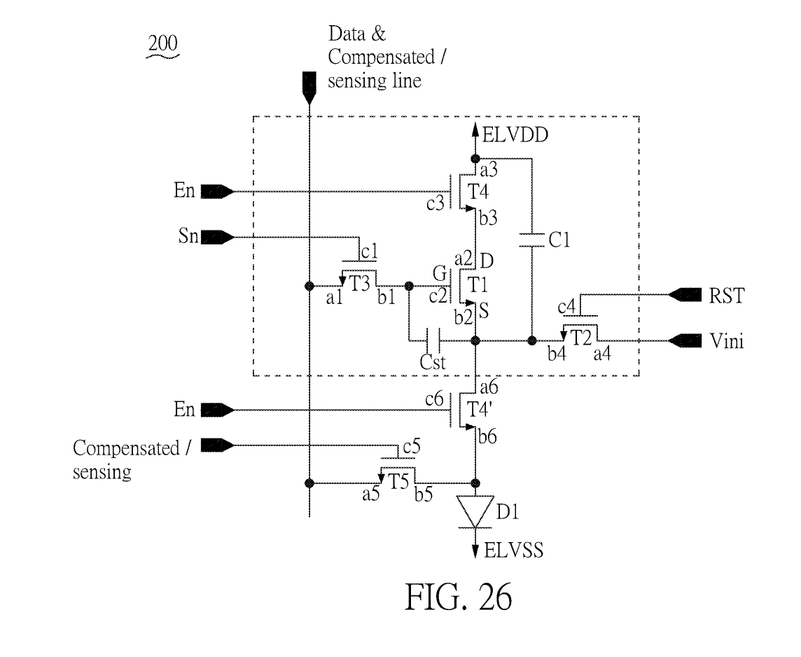

FIG. 26 is a circuit diagram of a pixel circuit 200 of active-matrix light-emitting diode according to a fifth embodiment of the present disclosure. In comparison with FIG. 3, the pixel circuit 200 in FIG. 26 further comprises a fifth transistor (T5) and a transistor (T4′). The fifth transistor (T5) has a fifth control terminal (c5) connected to a compensated/sensing signal, a tenth terminal (a5) connected to a data and compensated/sensing line, and an eleventh terminal (b5) connected to the light emitting diode (D1). The transistor (T4′) has a sixth control terminal (c6) connected to the second control signal (En), a twelfth terminal (a6) connected to the third terminal (b2), and a thirteen terminal (b6) connected to the eleventh terminal (b5) and the light emitting diode (D1). The connection for the remaining components is similar to that for FIG. 3, and thus a detailed description is deemed unnecessary.

As shown in FIG. 26, the fourth transistor (T4) and the transistor (T4′) are each a transistor comprising the polysilicon semiconductor layer. The first transistor (T1) is a transistor comprising the oxide semiconductor layer. The third transistor (T3), the second transistor (T2), and the fifth transistor (T5) are each a transistor comprising the polysilicon semiconductor layer or a transistor comprising the oxide semiconductor layer.

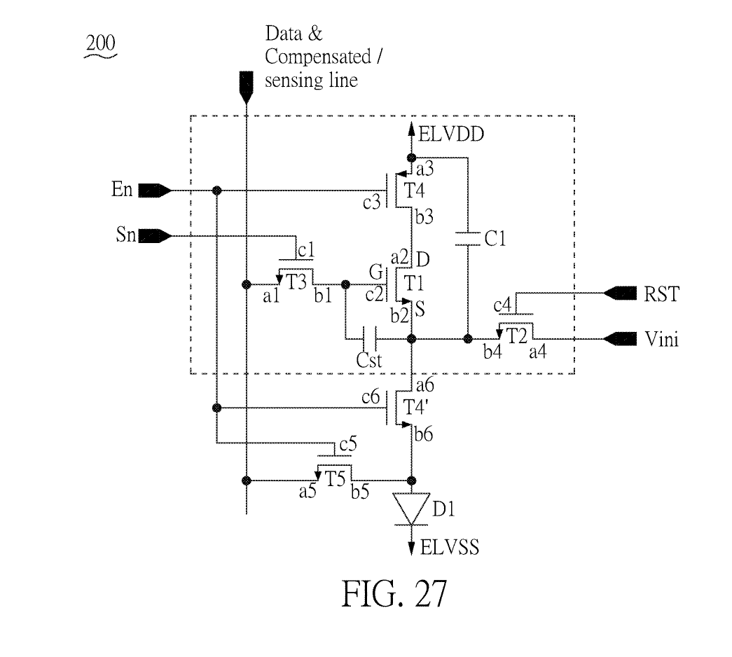

FIG. 27 is schematic view illustrating an application of the pixel circuit 200 of FIG. 26 according to the present disclosure, which is similar to FIG. 26 except that, in FIG. 27, the compensated/sensing signal of the pixel circuit 200 is removed, and the fifth control terminal (c5) is connected to the second control signal (En). In this example, the fourth transistor (T4) is a P-type transistor, and the fifth transistor (T5) is an N-type transistor.

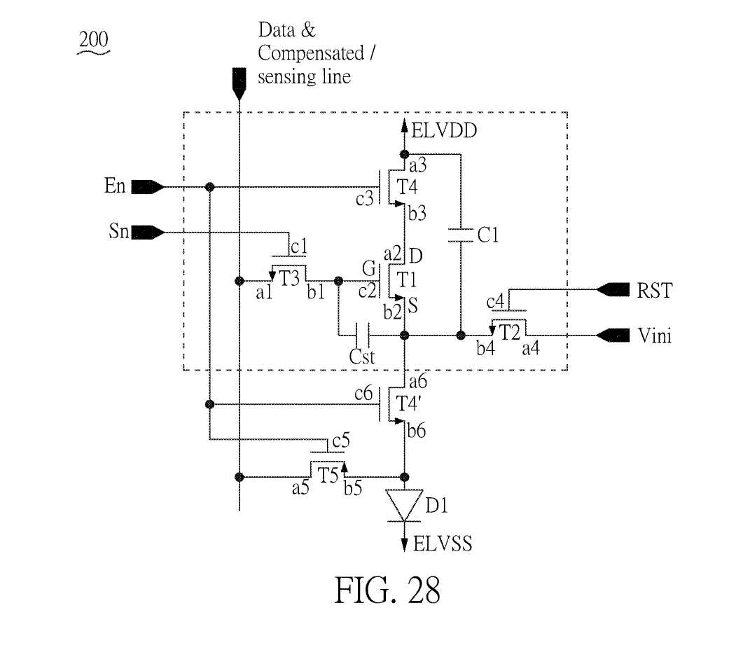

FIG. 28 is schematic view illustrating another application of the pixel circuit 200 of FIG. 26 according to the present disclosure, which is similar to FIG. 26 except that, in FIG. 28, the compensated/sensing signal of the pixel circuit 200 is removed, and the fifth control terminal (c5) is connected to the second control signal (En). In this example, the fourth transistor (T4) is an N-type transistor, and the fifth transistor (T5) is a P-type transistor.

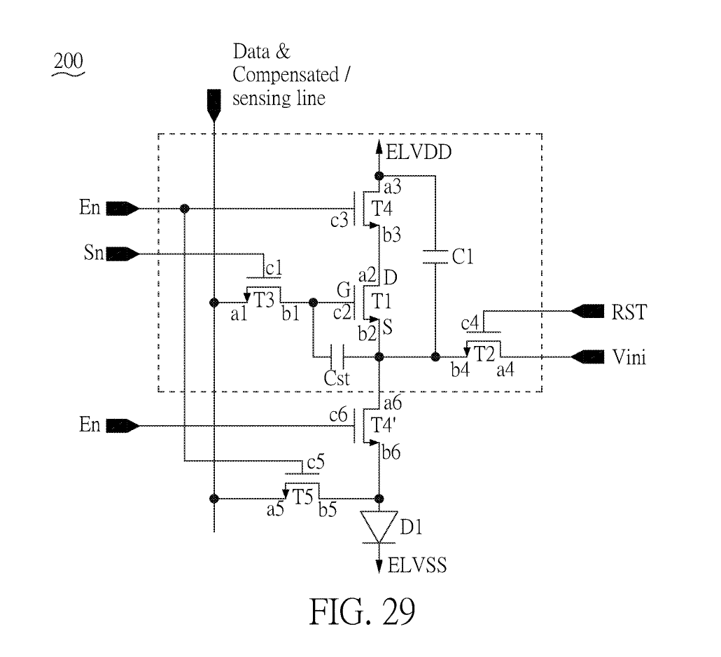

FIG. 29 is schematic view illustrating still another application of the pixel circuit 200 of FIG. 26 according to the present disclosure, which is similar to FIG. 26 except that, in FIG. 29, the compensated/sensing signal of the pixel circuit 200 is removed, and the fifth control terminal (c5) is connected to the first control signal (Sn).

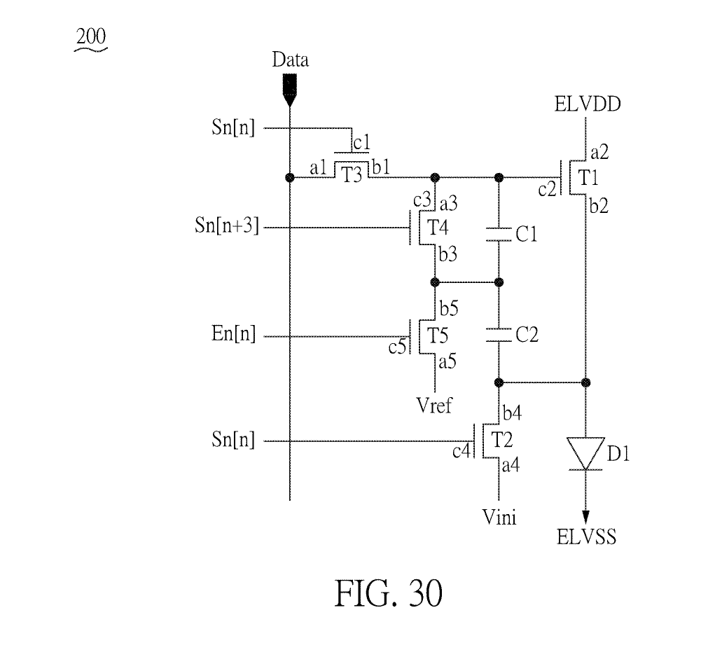

FIG. 30 is a circuit diagram of a pixel circuit 200 of active-matrix light-emitting diode according to a sixth embodiment of the present disclosure. As shown in FIG. 30, the pixel circuit 200 includes a third transistor (T3), a first transistor (T1), a first storage capacitor (C2), a fourth transistor (T4), a fifth transistor (T5), a second storage capacitor (C1) and a second transistor (T2). The pixel circuit 200 is used to drive a light emitting diode (D1).

The third transistor (T3) has a second control terminal (c1) connected to a first control signal (Sn[n]), a fourth terminal (a1) connected to a data line (Data), and a fifth terminal (b1). The first transistor (T1) has a first control terminal (c2) connected to the fifth terminal (b1), a second terminal (a2) connected to a high voltage (ELVDD), and a third terminal (b2). The second storage capacitor (C1) has one terminal connected to the first control terminal (c2) and the fifth terminal (b1).

The fourth transistor (T4) has a third control terminal (c3) connected to a second control signal (Sn[n+3]), a sixth terminal (a3) connected to the first control terminal (c2) and the fifth terminal (b1), and a seventh terminal (b3) connected to the other terminal of the second storage capacitor (C1). The fifth transistor (T5) has a fifth control terminal (c5) connected to a third control signal (En[n]), a tenth terminal (a5) connected to a reference voltage (Vref), and an eleventh terminal (b5) connected to the seventh terminal (b3) and one terminal of the first storage capacitor (C2). The other terminal of the first storage capacitor (C2) is connected to the third terminal (b2) and the light emitting diode (D1).

The second transistor (T2) has a fourth control terminal (c4) connected to a first control signal (Sn[n]), an eighth terminal (a4) connected to an initial signal (Vini), and a ninth terminal (b4) connected to the third terminal (b2). The anode of the light emitting diode (D1) is electrically connected to the third terminal (b2), and the cathode the light emitting diode (D1) is connected to a low voltage (ELVSS).

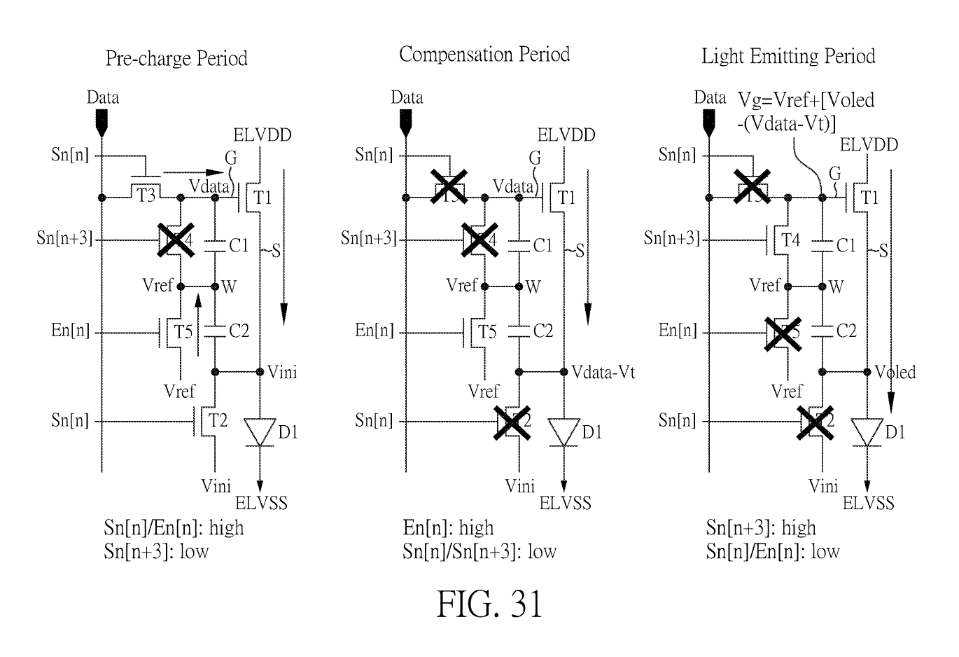

FIG. 31 is schematic diagram illustrating the operation of the pixel circuit 200 of FIG. 30 according to the present disclosure. As shown, in a pre-charge period, the first control signal (Sn[n]) is a high control voltage (VDD), the third control signal (En[n]) is the high control voltage (VDD), and the second control signal (Sn[n+3]) is a low control voltage (VSS). Therefore, the third transistor (T3), the first transistor (T1), the fifth transistor (T5), and the second transistor (T2) are turned on, and the fourth transistor (T4) is turned off. The voltage of the data line (Data) is a data write voltage (Vdata). Therefore, the voltage of node G is the data write voltage (Vdata), the voltage of node S is the voltage of the initial signal (Vini), and the voltage of node W is the voltage of the reference signal (Vref).

In a compensation period, the first control signal (Sn[n]) is the low control voltage (VSS), the second control signal (Sn[n+3]) is the low control voltage (VSS), and the third control signal (En[n]) is the high control voltage (VDD). Therefore, the first transistor (T1) and the fifth transistor (T5) are turned on, and the third transistor (T3), the second transistor (T2) and the fourth transistor (T4) are turned off. As a result, the voltage of node G is the data write voltage (Vdata), the voltage of node S is equal to Vdata−Vt, and the voltage of node W is the reference voltage (Vref), where Vdata is the data write voltage and Vt is the threshold voltage of the driving transistor (T1).

In a light emitting period, the first control signal (Sn[n]) is the low control voltage (VSS), the second control signal (Sn[n+3]) is the high control voltage (VDD), and the third control signal (En[n]) is the low control voltage (VSS). Therefore, the first transistor (T1) and the fourth transistor (T4) are turned on, and the third transistor (T3), the second transistor (T2) and the fifth transistor (T5) are turned off. As a result, the voltage of node G is equal to Vref+[V−(Vdata−Vt)], the voltage of node S is equal to V, and the voltage of node W is the reference voltage (Vref), where V is the voltage of the light emitting diode (D1), Vref is the reference voltage, and Vdata is the data write voltage. Owing to the voltage of node G being equal to the threshold voltage (Vt), in the light emitting period, it can compensate the threshold voltage variation resulted from the polycrystalline process and thus compensate the voltage across the light emitting diode (D1) for mitigating mura or poor brightness uniformity.

In one embodiment of present disclosure, the first transistor (T1) of the pixel circuit 200 of FIG. 30 is a transistor comprising the oxide semiconductor layer such that the threshold voltage (Vt) of the first transistor (T1) has better uniformity. The fourth transistor (T4) is a transistor comprising the polysilicon semiconductor layer such that the fourth transistor (T4) has better electron mobility and stability. The second transistor (T2) is a transistor comprising the polysilicon semiconductor layer for reducing circuit layout area. The third transistor (T3) and the fifth transistor (T5) are each a transistor comprising the polysilicon semiconductor layer or a transistor comprising the oxide semiconductor layer.

In another embodiment of present disclosure, the first transistor (T1) of the pixel circuit 200 of FIG. 30 is a transistor comprising the oxide semiconductor layer such that the threshold voltage (Vt) of the first transistor (T1) has better uniformity. The fourth transistor (T4) is a transistor comprising the polysilicon semiconductor layer such that the fourth transistor (T4) has better electron mobility and stability. The second transistor (T2) is a transistor comprising the polysilicon semiconductor layer for reducing circuit layout area. The third transistor (T3) is a transistor comprising the polysilicon semiconductor layer for reducing the pre-charge time. The fifth transistor (T5) is a transistor comprising the polysilicon semiconductor layer or the oxide semiconductor layer.

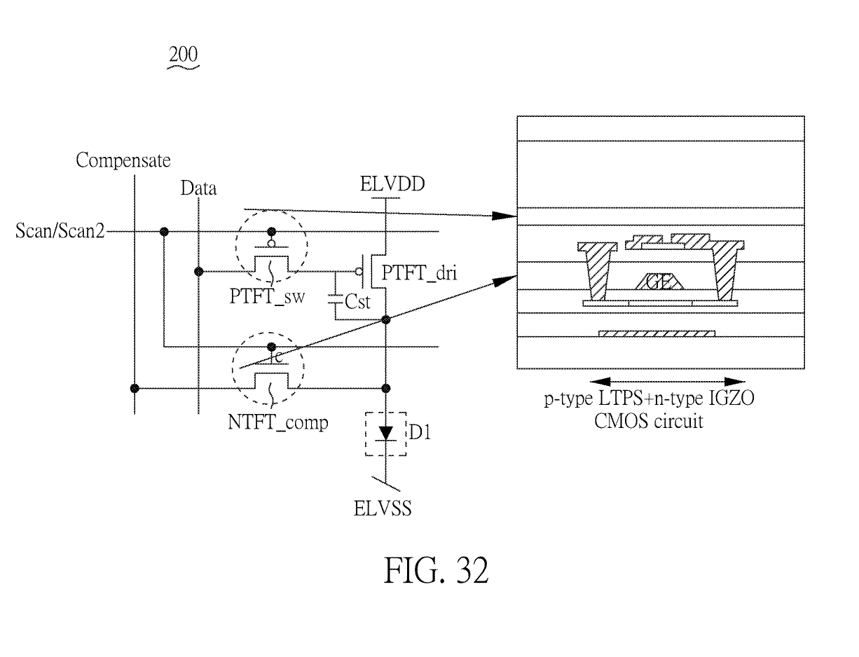

FIG. 32 is a circuit diagram of a pixel circuit 200 of active-matrix light-emitting diode according to a seventh embodiment of the present disclosure. As shown in FIG. 32, the pixel circuit 200 includes a third transistor (PTFT_sw), a first transistor (PTFT_dri), a first storage capacitor (Cst) and a second transistor (NTFT_comp). The pixel circuit 200 is used to drive a light emitting diode (D1), where the light emitting diode (D1) can be an organic light emitting diode or a LED chip.

As shown in FIG. 32, at first, the scan line (Scan/Scan2) is a low control voltage (VSS). The third transistor (PTFT_sw) is turned on, and the first transistor (PTFT_dri) and the second transistor (NTFT_comp) are turned off. The first storage capacitor (Cst) is charged by the voltage of the data line (Data).

Then, the scan line (Scan/Scan2) is a high control voltage (VSS). The third transistor (PTFT_sw) is turned off, and the first transistor (PTFT_dri) and the second transistor (NTFT_comp) are turned on. The light emitting diode (D1) is driven by a high voltage (ELVDD) through the first transistor (PTFT_dri). At this moment, owing to the second transistor (NTFT_comp) being turned on, the current of the light emitting diode (D1) is thus compensated by the compensation line (Compensate) through the second transistor (NTFT_comp).

The operation theory of the second transistor (NTFT_comp) is similar to that of the fifth transistor (T5) in FIG. 21. In a panel booting process, the compensation current of the light emitting diode (D1) is sensed and compensated by the second transistor (NTFT_comp). That is, in the panel booting process, the second transistor (NTFT_comp) compensates the current of the light emitting diode (D1), the third transistor (PTFT_sw) and the first transistor (PTFT_dri) are turned off, and the second transistor (NTFT_comp) is turned on. At this moment, an external sensing device (not shown) can sense the current of the light emitting diode (D1), so as to determine the magnitude of the compensation current and calculate the corresponding gate-source voltage (Vgs_comp) of the second transistor (NTFT_comp). In order to compensate the current of the light emitting diode (D1), the gate-source voltage (Vgs_comp) is applied to the control terminal (c) of the second transistor (NTFT_comp) via the scan line (Scan/Scan2). Therefore, the compensation current corresponding to the gate-source voltage (Vgs_comp) flows into the light emitting diode (D1) from the compensation line (Compensate) through the second transistor (NTFT_comp).

As shown in FIG. 32, the third transistor (PTFT_sw) can comprise the P-type polysilicon semiconductor layer, the second transistor (NTFT_comp) can comprise the N-type oxide semiconductor layer, and the first transistor (PTFT_dri) can comprise the polysilicon semiconductor layer or the oxide semiconductor layer. The second transistor (NTFT_comp) has a bottom gate structure and the third transistor (PTFT_sw) has a top gate structure. The second transistor (NTFT_comp) and the third transistor (PTFT_sw) can share a common gate. With the commonly-shared gate of the second transistor (NTFT_comp) and the third transistor (PTFT_sw), the second transistor (NTFT_comp) and the third transistor (PTFT_sw) have a stack-up structure in circuit layout, which can dramatically reduce the layout area.

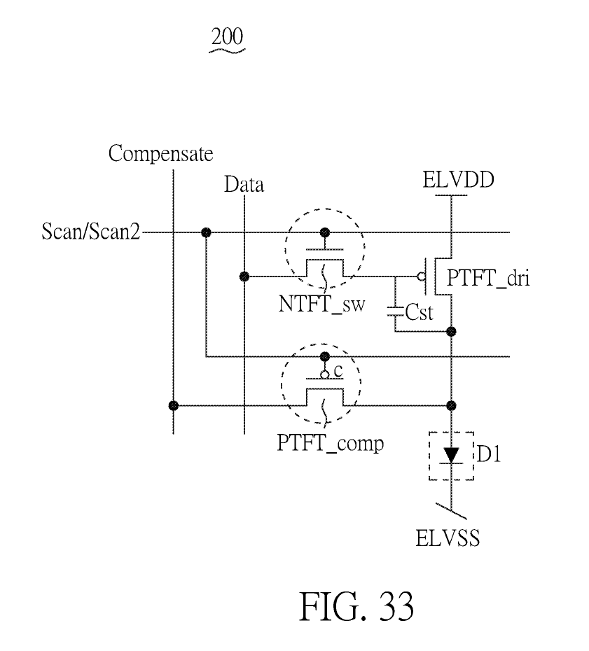

FIG. 33 is a circuit diagram of a pixel circuit 200 of active-matrix light-emitting diode according to an eighth embodiment of the present disclosure. In comparison with the pixel circuit 200 of FIG. 32, the third transistor (NTFT_sw) of the pixel circuit 200 of FIG. 33 is a transistor comprising an N-type oxide semiconductor layer and the second transistor (PTFT_comp) of the pixel circuit 200 in FIG. 33 is a transistor comprising a P-type polysilicon semiconductor layer.

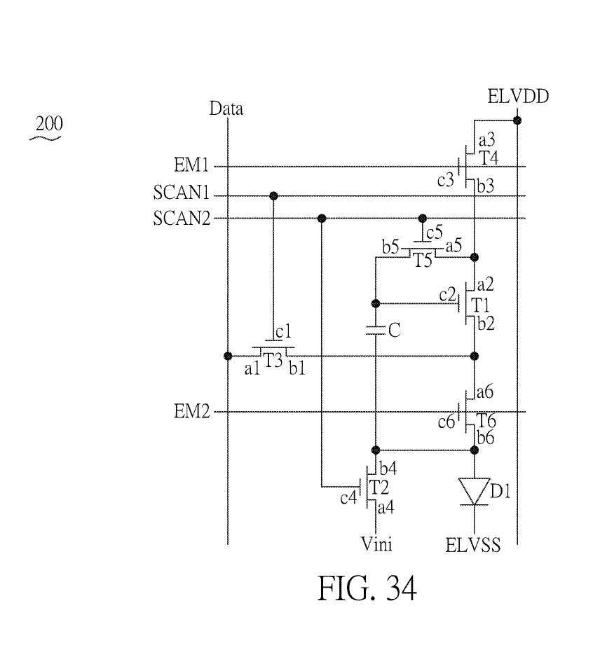

FIG. 34 is a circuit diagram of a pixel circuit 200 of active-matrix light-emitting diode according to a ninth embodiment of the present disclosure. As shown in FIG. 34, the pixel circuit 200 includes a third transistor (T3), a first transistor (T1), a first storage capacitor (C), a fourth transistor (T4), a fifth transistor (T5), a second transistor (T2) and a sixth transistor (T6). The pixel circuit 200 is used to drive a light emitting diode.

The third transistor (T3) has a second control terminal (c1) connected to a first control signal (SCAN1), a fourth terminal (a1) connected to a data line (Data), and a fifth terminal (b1). The first transistor (T1) has a first control terminal (c2) connected to one terminal of the first storage capacitor (C), a second terminal (a2), and a third terminal (b2) connected to the fifth terminal (b1).

The fourth transistor (T4) has a third control terminal (c3) connected to a second control signal (EM1), a sixth terminal (a3) connected to a high voltage (ELVDD), and a seventh terminal (b3) connected to the second terminal (a2). The fifth transistor (T5) has a fifth control terminal (c5) connected to a third control signal (SCAN2), a tenth terminal (a5) connected to the seventh terminal (b3), and an eleventh terminal (b5) connected to the first control terminal (c2) and one terminal of the first storage capacitor (C).

The second transistor (T2) has a fourth control terminal (c4) connected to the third control signal (SCAN2), an eighth terminal (a4) connected to an initial signal (Vini), and a ninth terminal (b4) connected to the other terminal of the first storage capacitor (C) and the light emitting diode (D1). The sixth transistor (T6) has a sixth control terminal (c6) connected to a fourth control signal (EM2), a twelfth terminal (a6) connected to the third terminal (b2) and the fifth terminal (b1), and a thirteenth terminal (b6) connected to the ninth terminal (b4) and the light emitting diode (D1).

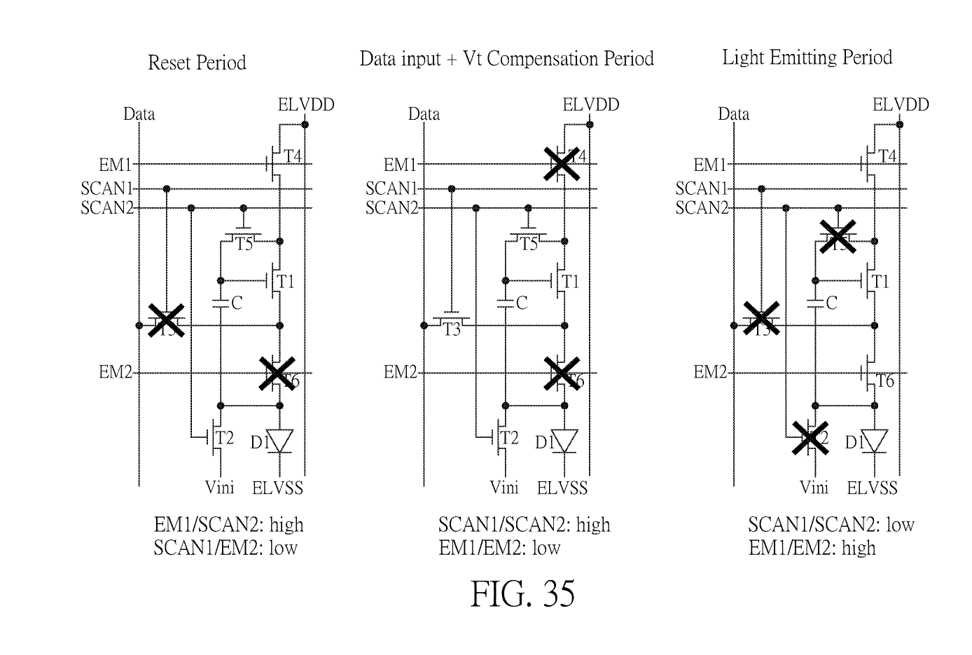

FIG. 35 is schematic diagram illustrating the operation of the pixel circuit 200 of FIG. 34 according to the present disclosure. As shown, in a reset period, the first control signal (SCAN1) is a low control voltage (VSS), the second control signal (EM1) is a high control voltage (VDD), the third control signal (SCAN2) is the high control voltage (VDD), and the fourth control signal (EM2) is the low control voltage (VSS). Therefore, the third transistor (T3) and the sixth transistor (T6) are turned off, and the first transistor (T1), the fourth transistor (T4), the fifth transistor (T5) and the second transistor (T2) are turned on.

In a data input and Vt compensation period, the first control signal (SCAN1) is the high control voltage (VDD), the second control signal (EM1) is the low control voltage (VSS), the third control signal (SCAN2) is the high control voltage (VDD), and the fourth control signal (EM2) is the low control voltage (VSS). Therefore, the fourth transistor (T4) and the sixth transistor (T6) are turned off, and the first transistor (T1), the third transistor (T3), the fifth transistor (T5) and the second transistor (T2) are turned on.

In a light emitting period, the first control signal (SCAN1) is the low control voltage (VSS), the second control signal (EM1) is the high control voltage (VDD), the third control signal (SCAN2) is the low control voltage (VSS), and the fourth control signal (EM2) is the high control voltage (VDD). Therefore, the third transistor (T3), the fifth transistor (T5) and the second transistor (T2) are turned off, and the first transistor (T1), the fourth transistor (T4) and the sixth transistor (T6) are turned on. The operation theory of threshold voltage (Vt) compensation of FIG. 35 is similar to that of FIG. 4a to FIG. 4d. In the light emitting period, it can thus compensate the threshold voltage variation caused by the polycrystalline process and compensate the voltage across the light emitting diode (D1) for mitigating mura or poor brightness uniformity.

In one embodiment of the present disclosure, the fourth transistor (T4) and the sixth transistor (T6) of FIG. 34 are each a transistor comprising the polysilicon semiconductor layer, and the third transistor (T3), the first transistor (T1), the fifth transistor (T5) and the second transistor (T2) are each a transistor comprising the polysilicon semiconductor layer or a transistor comprising the oxide semiconductor layer.

In another embodiment of the present disclosure, the fourth transistor (T4) and the sixth transistor (T6) of FIG. 34 are each a transistor comprising the polysilicon semiconductor layer such that the fourth transistor (T4) and the sixth transistor (T6) have better electron mobility and stability. The first transistor (T1) is a transistor comprising the oxide semiconductor layer such that the threshold voltage (Vt) of the first transistor (T1) has better uniformity. The second transistor (T2) is a transistor comprising the polysilicon semiconductor layer for reducing circuit layout area. The third transistor (T3) is a transistor comprising the polysilicon semiconductor layer for reducing the pre-charge time. The fifth transistor (T5) is a transistor comprising the polysilicon semiconductor layer or a transistor comprising the oxide semiconductor layer.

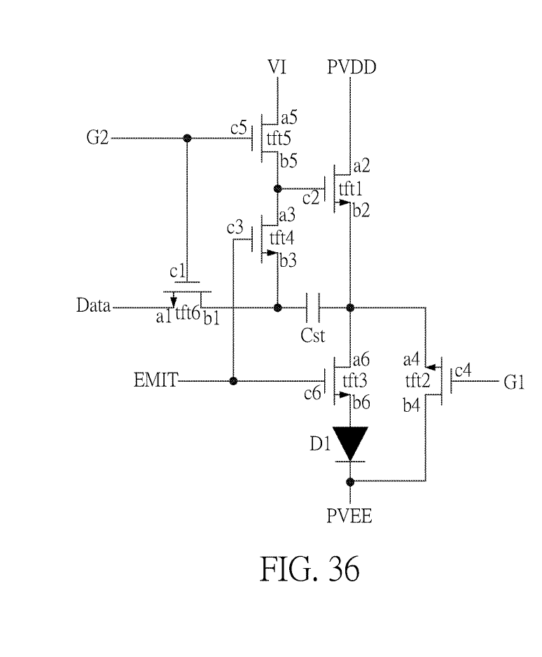

FIG. 36 is a circuit diagram of a pixel circuit 200 of active-matrix light-emitting diode according to a tenth embodiment of the present disclosure, where the light emitting diode (D1) can be an organic light emitting diode or a LED chip. As shown, the pixel circuit 200 includes a third transistor (tft6), a first transistor (tft1), a first storage capacitor (Cst), a fourth transistor (tft4), a fifth transistor (tft5), a second transistor (tft2) and a sixth transistor (tft3). The pixel circuit 200 is used to drive a light emitting diode (D1).

The third transistor (tft6) has a second control terminal (c1) connected to a first control signal (G2), a fourth terminal (a1) connected to a data line (Data), and a fifth terminal (b1). The first transistor (tft1) has a first control terminal (c2), a second terminal (a2) connected to a high voltage (PVDD), and a third terminal (b2) connected to one terminal of the first storage capacitor (Cst).

The fourth transistor (tft4) has a third control terminal (c3) connected to a second control signal (EMIT), a sixth terminal (a3) connected to the first control terminal (c2) of the driving transistor (tft1), and a seventh terminal (b3) connected to the other terminal of the first storage capacitor (Cst). The fifth transistor (tft5) has a fifth control terminal (c5) connected to the first control signal (G2), a tenth terminal (a5) connected to a third control signal (VI), and an eleventh terminal (b5) connected to the first control terminal (c2) of the first transistor (tft1).

The second transistor (tft2) has a fourth control terminal (c4) connected to a fourth control signal (G1), an eighth terminal (a4) connected to the third terminal (b2) of the first transistor (tft1) and one terminal of the first storage capacitor (Cst), and a ninth terminal (b4) connected to the cathode of the light emitting diode (D1) and a low voltage (PVEE). The sixth transistor (tft3) has a sixth control terminal (c6) connected to the second control signal (EMIT), a twelfth terminal (a6) connected to the third terminal (b2) of the first transistor (tft1), and a thirteenth terminal (b6) connected to the anode of the light emitting diode (D1).

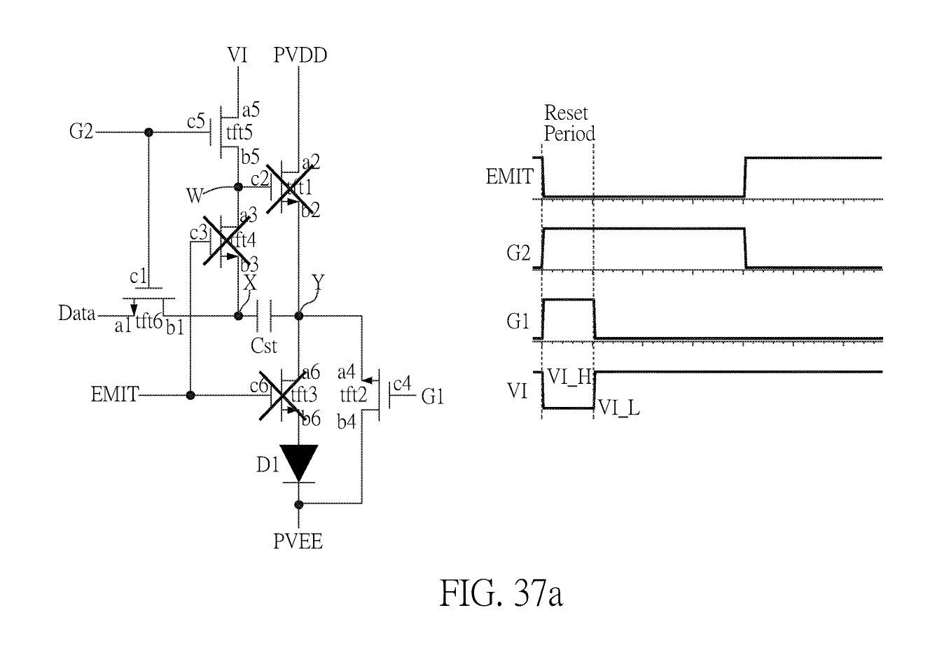

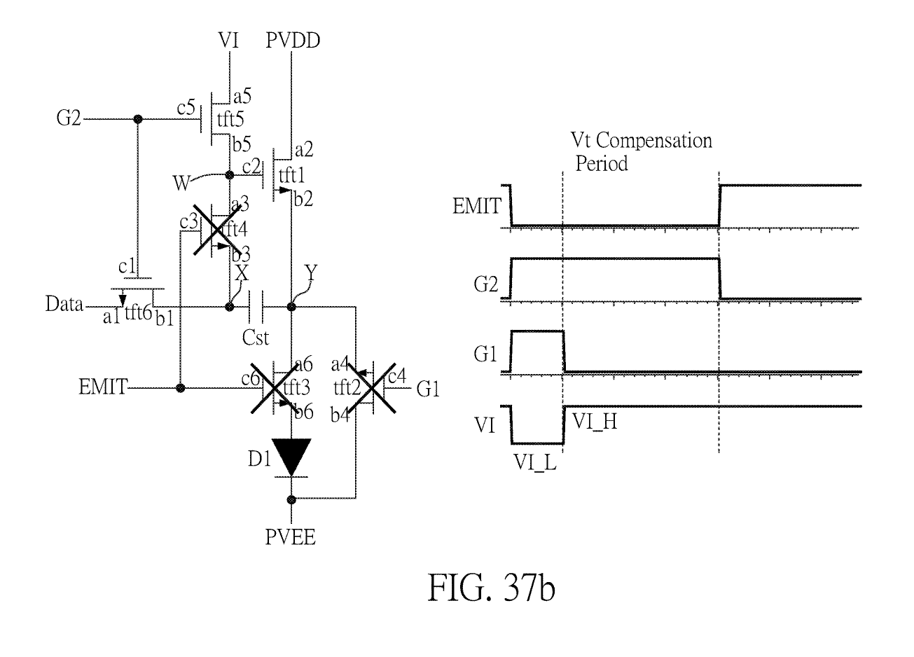

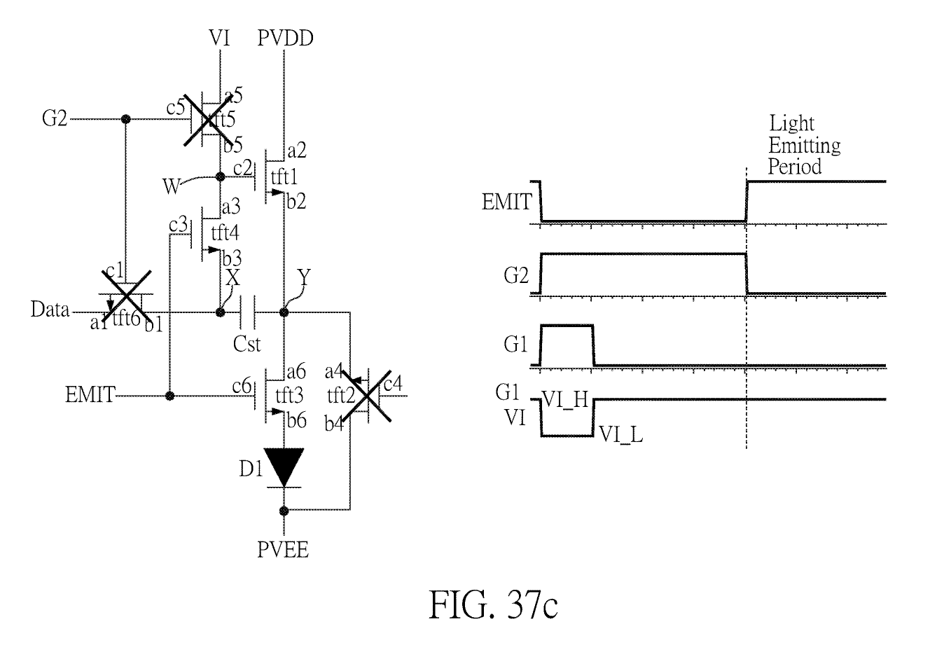

FIG. 37a to FIG. 37c are schematic diagrams illustrating the operation of the pixel circuit 200 of FIG. 36 according to the present disclosure. As shown in FIG. 37a, in a reset period, the first control signal (G2) is a high control voltage (VDD), the second control signal (EMIT) is a low control voltage (VSS), the third control signal (VI) is the low control voltage (VSS), and the fourth control signal (G1) is the high control voltage (VDD). Therefore, the fourth transistor (tft4), the first transistor (tft1) and the sixth transistor (tft3) are turned off, and the third transistor (tft6), the fifth transistor (tft5) and the second transistor (tft2) are turned on. Accordingly, the voltage of node X is Vdata and the voltage of node Y is the voltage of PVEE, where Vdata is the voltage of the data line (Data) and PVEE is the low voltage. It is noted that the voltage of the third control signal (VI) can be a low voltage VI_L which drives the first transistor (tft1) into a turn-off state for preventing the light emitting diode (D1) from emitting light. The low voltage VI_L can be equal to or different from that of the low control voltage (VSS).

As shown in FIG. 37b, in a Vt compensation period, the first control signal (G2) is the high control voltage (VDD), the second control signal (EMIT) is the low control voltage (VSS), the third control signal (VI) is the high control voltage (VDD), and the fourth control signal (G1) is the low control voltage (VSS). Therefore, the fourth transistor (tft4), the second transistor (tft2) and the sixth transistor (tft3) are turned off, and the third transistor (tft6), the fifth transistor (tft5) and the first transistor (tft1) are turned on. As a result, the voltage of node X is Vdata and the voltage of node Y is equal to VI_H−Vt1, where Vdata is the voltage of the data line, VI_H is a high voltage of the third control signal (VI), and Vt1 is the threshold voltage of the first transistor (tft1). The high voltage VI_H can be equal to or different from that of the high control voltage (VDD).

As shown in FIG. 37c, in a light emitting period, the first control signal (G2) is the low control voltage (VSS), the second control signal (EMIT) is the high control voltage (VDD), the third control signal (VI) is the high control voltage (VDD), and the fourth control signal (G1) is the low control voltage (VSS). Therefore, the second transistor (tft2), the third transistor (tft6) and the fifth transistor (tft5) are turned off, and the fourth transistor (tft4), the sixth transistor (tft3) and the first transistor (tft1) are turned on. As a result, the voltage of node X is equal to Vdata+V−VI_H+Vt1 and the voltage of node Y is equal to V, where V is the voltage of the anode of the light emitting diode (D1). Owing to the fourth transistor (tft4) being turned on, the voltage of node W is equal to the voltage of node X, and the voltage of node W is thus equal to Vdata+V−VI_H+Vt1. The voltage (Vgs) between the gate and the source of the first transistor (tft1) is equal to Vdata−VI_H+Vt1. Because the voltage of node W is equal to the threshold voltage (Vt1), in the light emitting period, it can compensate the threshold voltage variation caused by the polycrystalline process and compensate the voltage across the light emitting diode (D1) for mitigating mura or poor brightness uniformity.

In one embodiment of the present disclosure, the fourth transistor (tft4) and the sixth transistor (tft3) of FIG. 36 are each a transistor comprising the polysilicon semiconductor layer, the first transistor (tft1) is a transistor comprising the oxide semiconductor layer, and the third transistor (tft6), the fifth transistor (tft5) and the second transistor (tft2) are each a transistor comprising the polysilicon semiconductor layer or a transistor comprising the oxide semiconductor layer.

FIG. 38 is a circuit diagram of a pixel circuit 200 of active-matrix light-emitting diode according to an eleventh embodiment of the present disclosure. As shown, the pixel circuit 200 includes a third transistor (tft6), a first transistor (tft1), a first storage capacitor (Cst), a fourth transistor (tft4), a fifth transistor (tft5), a second transistor (tft2) and a sixth transistor (tft3). The pixel circuit 200 is used to drive a light emitting diode (D1).

The third transistor (tft6) has a second control terminal (c1) connected to a first control signal (XEMIT), a fourth terminal (a1) connected to a data line (Data), and a fifth terminal (b1). The first transistor (tft1) has a first control terminal (c2) connected to the fifth terminal (b1), a second terminal (a2) connected to a high voltage (PVDD), and a third terminal (b2) connected to one terminal of the first storage capacitor (Cst).

The fourth transistor (tft4) has a third control terminal (c3) connected to a second control signal (EMIT), a sixth terminal (a3) connected to the first control terminal (c2), and a seventh terminal (b3) connected to the other terminal of the first storage capacitor (Cst). The fifth transistor (tft5) has a fifth control terminal (c5) connected to the first control signal (XEMIT), a tenth terminal (a5) connected to the second control signal (EMIT), and an eleventh terminal (b5) connected to a reference voltage (VREF).

The second transistor (tft2) has a fourth control terminal (c4) connected to a third control signal (G1), an eighth terminal (a4) connected to the third terminal (b2) and one terminal of the first storage capacitor (Cst), and a ninth terminal (b4) connected to the cathode of the light emitting diode (D1). The sixth transistor (tft3) has a sixth control terminal (c6) connected to the second control signal (EMIT), the third control terminal (c3) and the seventh terminal (b3), an twelfth terminal (a6) connected to the third terminal (b2), and a thirteenth terminal (b6) connected to the anode of the light emitting diode (D1).

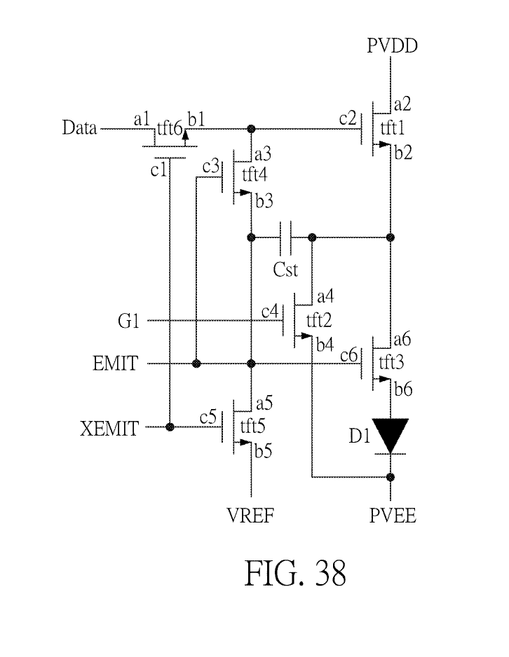

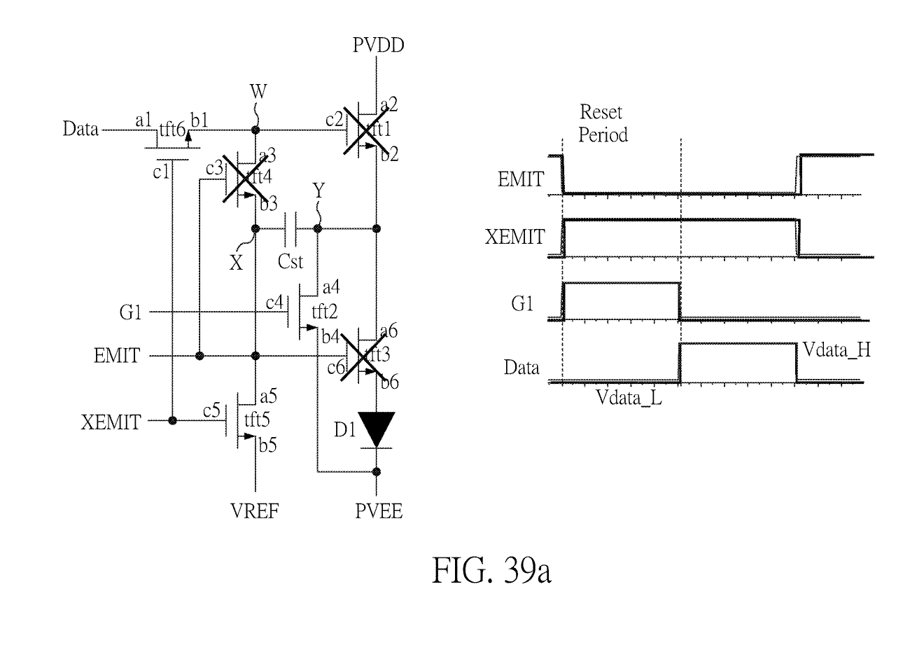

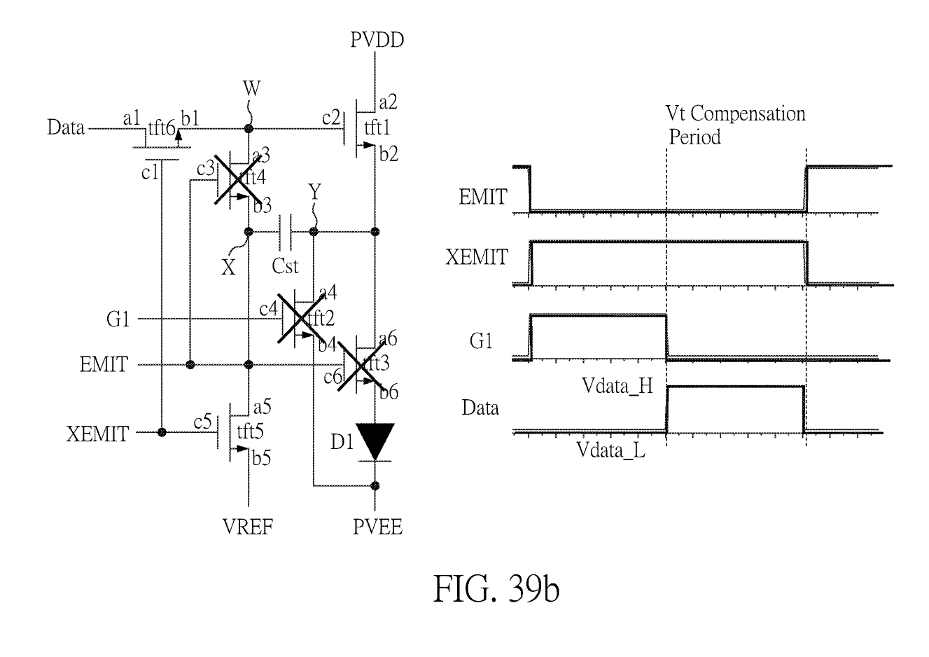

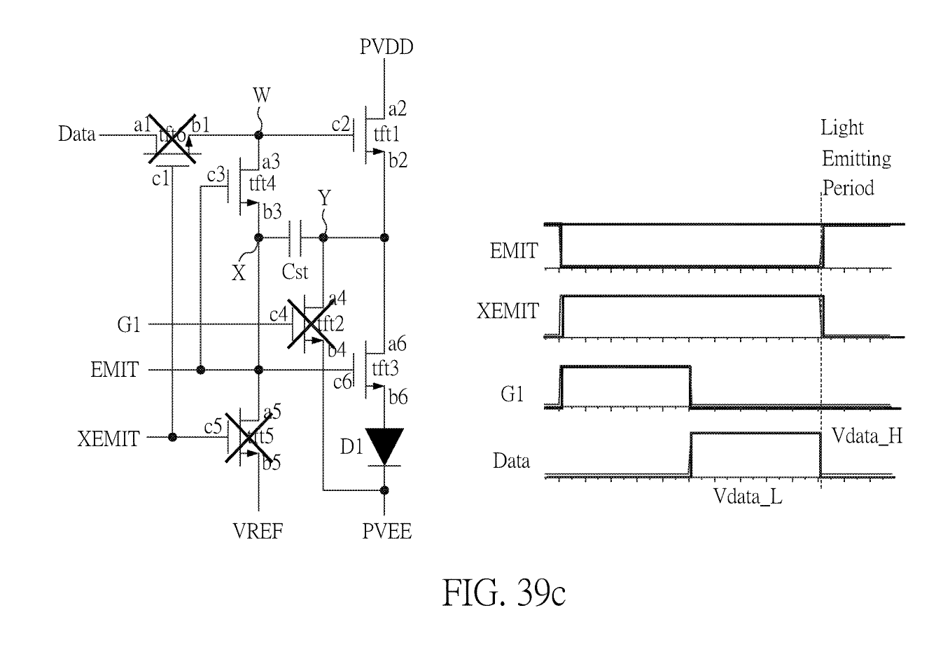

FIG. 39a to FIG. 39c are schematic diagrams illustrating the operation of the pixel circuit 200 of FIG. 38 according to the present disclosure. As shown in FIG. 39a, in a reset period, the first control signal (XEMIT) is a high control voltage (VDD), the second control signal (EMIT) is a low control voltage (VSS), the third control signal (G1) is the high control voltage (VDD), and the voltage of the data line is a low voltage (Vdata_L). The low voltage (Vdata_L) can be equal to or different from that of the low control voltage (VSS). Therefore, the first transistor (tft1), the sixth transistor (tft3) and the fourth transistor (tft4) are turned off, and the third transistor (tft6), the fifth transistor (tft5) and the second transistor (tft2) are turned on. As a result, the voltage of node X is VREF, the voltage of node Y is the voltage of PVEE, and the voltage of node W is the voltage of Vdata_L, where Vdata_L is the voltage of the data line, PVEE is the low voltage, and VREF is the low voltage of the reference voltage. It is noted that the voltage of node W (Vdata_L) can be a low voltage which drives the first transistor (tft1) into a turn-off state for preventing the light emitting diode (D1) from emitting light.

As shown in FIG. 39b, in a Vt compensation period, the first control signal (XEMIT) is the high control voltage (VDD), the second control signal (EMIT) is the low control voltage (VSS), the third control signal (G1) is the low control voltage (VSS), and the voltage of the data line is a high voltage (Vdata_H). The high voltage (Vdata_H) can be equal to or different from that of the high control voltage (VDD). Therefore, the fourth transistor (tft4), the second transistor (tft2) and the sixth transistor (tft3) are turned off, and the third transistor (tft6), the first transistor (tft1) and the fifth transistor (tft5) are turned on. As a result, the voltage of node X is VREF, the voltage of node Y is equal to Vdata_H−Vt1, and the voltage of node W is equal to Vdata_H, where Vdata_H is the high voltage of the data line, and Vt1 is the threshold voltage of the first transistor (tft1).

As shown in FIG. 39c, in a light emitting period, the first control signal (XEMIT) is the low control voltage (VSS), the second control signal (EMIT) is the high control voltage (VDD), the third control signal (G1) is the low voltage (VSS), and the voltage of the data line is the low voltage (Vdata_L). Therefore, the second transistor (tft2), the fifth transistor (tft5) and the third transistor (tft6) are turned off, and the fourth transistor (tft4), the sixth transistor (tft3) and the first transistor (tft1) are turned on. As a result, the voltage of node X is equal to VREF+V−Vdata_H+Vt1 and the voltage of node Y is equal to V, where V is the voltage of the anode of the light emitting diode (D1). Owing to the fourth transistor (tft4) being turned on, the voltage of node W is equal to the voltage of node X. Thus, the voltage of node W is equal to VREF+V−Vdata_H+Vt1. The voltage (Vgs) between the gate and the source of the first transistor (tft1) is equal to VREF−Vdata_H+Vt1. The current flowing through the first transistor (tft1) is equal to ½kn′(VREF−Vdata_H)², where kn′ is the transconductance parameter of a MOSFET. In this current equation, the term Vt1 has been eliminated, which indicates that the threshold voltage of the first transistor (tft1) has been compensated. Owing to the voltage of node W being equal to the threshold voltage (Vt1), in the light emitting period, it can compensate the threshold voltage variation caused by the polycrystalline process and compensate the voltage across the light emitting diode (D1) for mitigating mura or poor brightness uniformity.

In one embodiment of the present disclosure, the fourth transistor (tft4) and the sixth transistor (tft3) of FIG. 38 are each a transistor comprising the polysilicon semiconductor layer, the first transistor (tft1) is a transistor comprising the oxide semiconductor layer, and the third transistor (tft6), the fifth transistor (tft5) and the second transistor (tft2) are each a transistor comprising the polysilicon semiconductor layer or a transistor comprising the oxide semiconductor layer.

Although the present disclosure has been explained in relation to its preferred example, it is to be understood that many other possible modifications and variations can be made without departing from the spirit and scope of the disclosure as hereinafter claimed.

What is claimed is:

1. A display comprising:
a pixel circuit, comprising:
a light emitting diode;
a first transistor comprising a first semiconductor layer, the first transistor having a first control terminal, a second terminal and a third terminal, wherein the third terminal is electrically connected to the light emitting diode;
a second transistor comprising a second semiconductor layer, the second transistor being electrically connected to the third terminal; and
a third transistor electrically connected to the first control terminal,
wherein a material of the first semiconductor layer is different from a material of the second semiconductor layer.

2. The display of claim 1, wherein the first semiconductor layer is an oxide semiconductor layer, and wherein the second semiconductor layer is a silicon semiconductor layer.

3. The display of claim 2, wherein the third transistor comprises a third semiconductor layer, and the third semiconductor layer is an oxide semiconductor layer.

4. The display of claim 2, wherein the third transistor comprises a third semiconductor layer, and the third semiconductor layer is a silicon semiconductor layer.

5. The display of claim 1, wherein the first semiconductor layer comprises a silicon semiconductor layer, and the second semiconductor layer comprises an oxide semiconductor layer.

6. The display of claim 5, wherein the third transistor comprises a third semiconductor layer, and the third semiconductor layer is an oxide semiconductor layer.

7. The pixel circuit of claim 5, wherein the third transistor comprises a third semiconductor layer, and the third semiconductor layer is a silicon semiconductor layer.

8. The display of claim 1, wherein the second transistor further comprises a first gate electrode overlapped with the second semiconductor layer and a second gate electrode overlapped with the second semiconductor layer.

9. A display comprising:
a pixel circuit, comprising:
a light emitting diode;
a first transistor having a first control terminal, a second terminal and a third terminal, wherein the third terminal is electrically connected to the light emitting diode;
a second transistor comprising a second semiconductor layer, the second transistor being electrically connected to the third terminal; and
a third transistor comprising a third semiconductor layer, the third transistor being electrically connected to the first control terminal,
wherein a material of the second semiconductor layer is different from a material of the third semiconductor layer.

10. The display of claim 9, wherein the second semiconductor layer is a silicon semiconductor layer, and wherein the third semiconductor layer is an oxide semiconductor layer.

11. The display of claim 10, wherein the first transistor comprises a first semiconductor layer, and the first semiconductor layer is an oxide semiconductor layer.

12. The display of claim 10, wherein the first transistor comprises a first semiconductor layer, and the first semiconductor layer is a silicon semiconductor layer.

13. The display of claim 9, wherein the second semiconductor layer is an oxide semiconductor layer, and the third semiconductor layer is a silicon semiconductor layer.

14. The display of claim 13, wherein the first transistor comprises a first semiconductor layer, and the first semiconductor layer is an oxide semiconductor layer.

15. The pixel circuit of claim 13, wherein the first transistor comprises a first semiconductor layer, and the first semiconductor layer is a silicon semiconductor layer.

16. The display of claim 9, wherein the second transistor further comprises a first gate electrode overlapped with the second semiconductor layer and a second gate electrode overlapped with the second semiconductor layer.
